(19) United States
(12) Patent Application Publication
(10) Pub. No.: US 2026/0123085 A1
(43) Pub. Date: Apr. 30, 2026

(54) TERAHERTZ DEVICE

(71) Applicant: ROHM CO., LTD., Kyoto (JP)

(72) Inventor: Yosuke NISHIDA, Kyoto-shi (JP)

(73) Assignee: ROHM CO., LTD., Kyoto (JP)

(21) Appl. No.: 19/429,693

(22) Filed: Dec. 22, 2025

Related U.S. Application Data
(63) Continuation of application No. PCT/JP2024/018984, filed on May 23, 2024.

(30) Foreign Application Priority Data
Jun. 29, 2023 (JP) 2023-106932

(51) Int. Cl. H10F 55/00

(52) U.S. Cl. CPC H10F 55/18

(57) ABSTRACT

A terahertz device includes slots formed in a conductive layer, connection slits formed in the conductive layer, and active elements disposed in the slots. The slots are annular. The conductive layer includes first electrodes defined by the slots, a connection line disposed in the connecting slits and electrically connecting the first electrodes located inside two adjacent ones of the slots, and a second electrode located outside the slots. Each of the connecting slits connects the two adjacent ones of the slots and insulates the connection line from the second electrode. The active elements include two active elements provided for each of the first electrodes. The two active elements are located at opposite sides of the corresponding one of the first electrodes with respect to a center of the corresponding one of the slots in a plan view taken from a direction orthogonal to the front surface.

### CROSS-REFERENCE TO RELATED APPLICATIONS

This application is a continuation of, and claims the benefit of priority from International Application No. PCT/JP2024/018984, filed on May 23, 2024, which claims the benefit of priority from Japanese Patent Application No. 2023-106932, filed on June 29, 2023, the entire contents of each are incorporated herein by reference.

### BACKGROUND

### 1. Field

The present disclosure relates to a terahertz device.

### 2. Description of Related Art

The trend toward miniaturization of electronic devices such as transistors has led to nano-scale devices that exhibit quantum effects. Ultrahigh-speed devices and novel functional devices that utilize quantum effects are currently under development.

In such an environment, there is ongoing research aimed at utilizing electromagnetic waves in the frequency range referred to as the terahertz band, which covers frequencies from 0.1 THz to 10 THz, for large-capacity communication, information processing, imaging, and measurement. This frequency range exhibits characteristics of both light and radio waves. Therefore, if devices capable of operating in this frequency band can be developed, they may be applied to a wide variety of fields, including physical property analysis, astronomy, and biology, in addition to imaging, large-capacity communication, and information processing.

A known example of an element that emits or receives electromagnetic waves having a frequency in the terahertz band is a terahertz device constructed by integrating a resonant tunneling diode and a micro-antenna (refer to, for example, JP2020-115500A).

### BRIEF DESCRIPTION OF DRAWINGS

FIG. 1 is a schematic plan view of an exemplary terahertz device in accordance with a first embodiment.

FIG. 2 is a schematic perspective view of the terahertz device illustrated in FIG. 1.

FIG. 3 is a schematic cross-sectional view taken along line F3-F3 in FIG. 1.

FIG. 4 is a schematic plan view illustrating the arrangement of ring slots, connecting slits, and active elements in the terahertz device of FIG. 1.

FIG. 5 is a schematic plan view of an active element in the terahertz device of FIG. 1.

FIG. 6 is a schematic plan view of an active element in the terahertz device of FIG. 1.

FIG. 7 is a schematic cross-sectional view of the active elements illustrated in FIGS. 5 and 6.

FIG. 8 is a schematic plan view of a resistive element illustrated in FIG. 1.

FIG. 9 is a schematic cross-sectional view of the resistive element illustrated in FIG. 8.

FIG. 10 is a schematic plan view of an exemplary terahertz device in accordance with a second embodiment.

FIG. 11 is an enlarged plan view of the terahertz device illustrated in FIG. 10.

FIG. 12 is a schematic plan view of an exemplary terahertz device in accordance with a third embodiment.

FIG. 13 is a schematic plan view of an exemplary terahertz device in accordance with a fourth embodiment.

FIG. 14 is a schematic plan view of an exemplary terahertz device in accordance with a fifth embodiment.

FIG. 15 is a schematic plan view of an exemplary terahertz device in accordance with a sixth embodiment.

FIG. 16 is a schematic plan view of an exemplary terahertz device in accordance with a seventh embodiment.

FIG. 17 is a schematic plan view of an exemplary terahertz device in accordance with an eighth embodiment.

FIG. 18 is a schematic plan view of an active element in the terahertz device of FIG. 17.

FIG. 19 is a schematic plan view of an active element in the terahertz device of FIG. 17.

FIG. 20 is a schematic cross-sectional view of the active element and a resistive element that are illustrated in FIG. 19.

### DETAILED DESCRIPTION

Several embodiments of a terahertz device in accordance with the present disclosure will now be described with reference to the accompanying drawings. Elements in the figures are illustrated for simplicity and clarity and have not necessarily been drawn to scale. To aid understanding, hatching lines may not be shown in the cross-sectional drawings. The accompanying drawings illustrate exemplary embodiments in accordance with the present disclosure and are not intended to limit the present disclosure. Terms such as “first,” “second,” and “third” in this disclosure are used to distinguish subjects and not used for ordinal purposes.

The detailed description hereafter provides a comprehensive understanding of exemplary methods, apparatuses, and/or systems in accordance with the present disclosure. This detailed description is illustrative and is not intended to limit embodiments of the present disclosure or the application and use of the embodiments.

In this specification, the phrase “at least one of” as used in this disclosure means “one or more” of a desired choice. As one example, the phrase “at least one of” as used in this disclosure includes “only one of the two choices” and “both of the two choices” in a case where the number of choices is two. In another example, the phrase “at least one of” as used in this disclosure includes “only one single choice” and “any combination of two or more choices” if the number of its choices is three or more.

A terahertz device is used as a light source that emits electromagnetic waves having a frequency in the terahertz band or as a detector that detects electromagnetic waves having a frequency in the terahertz band. It is desirable for such a terahertz device to have higher output and improved resolution characteristics.

### First Embodiment

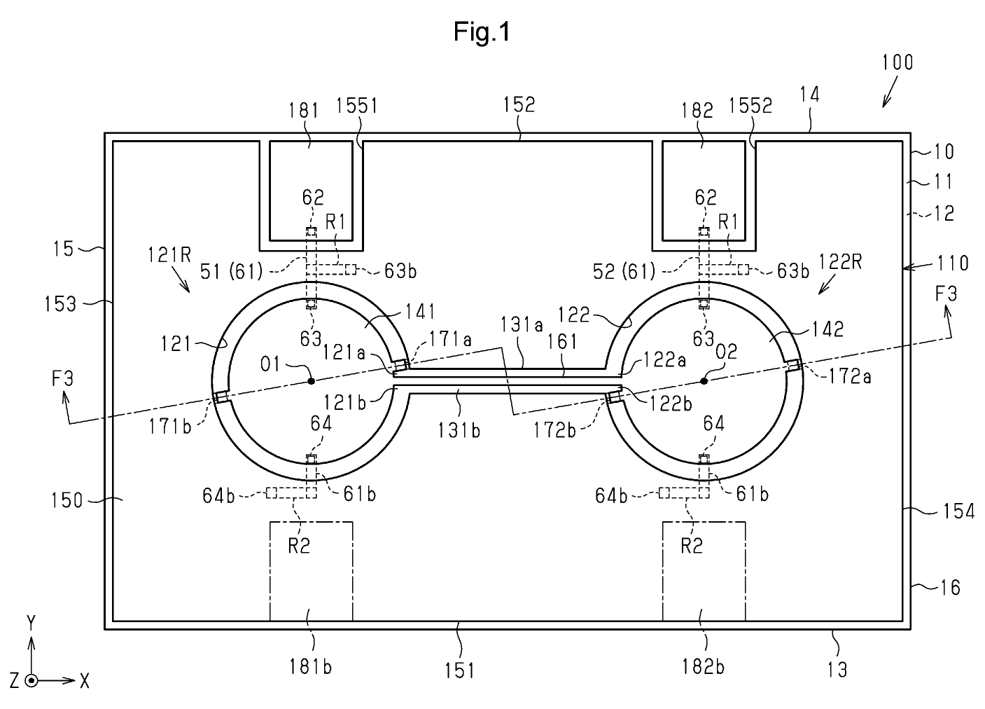

With reference to FIGS. 1 to 9, a terahertz device 100 in accordance with a first embodiment will now be described.

### Schematic Configuration of Terahertz Device

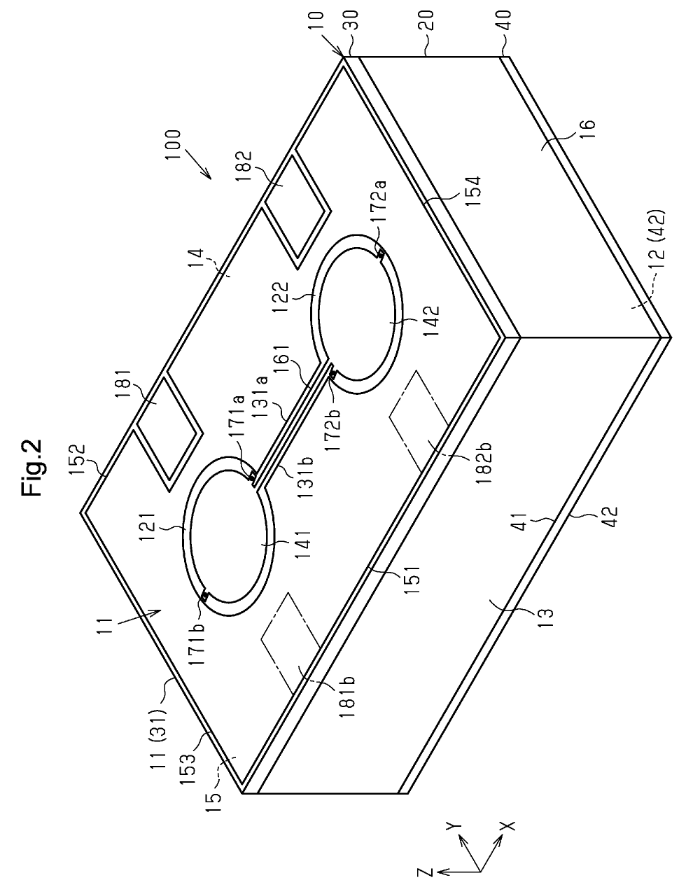

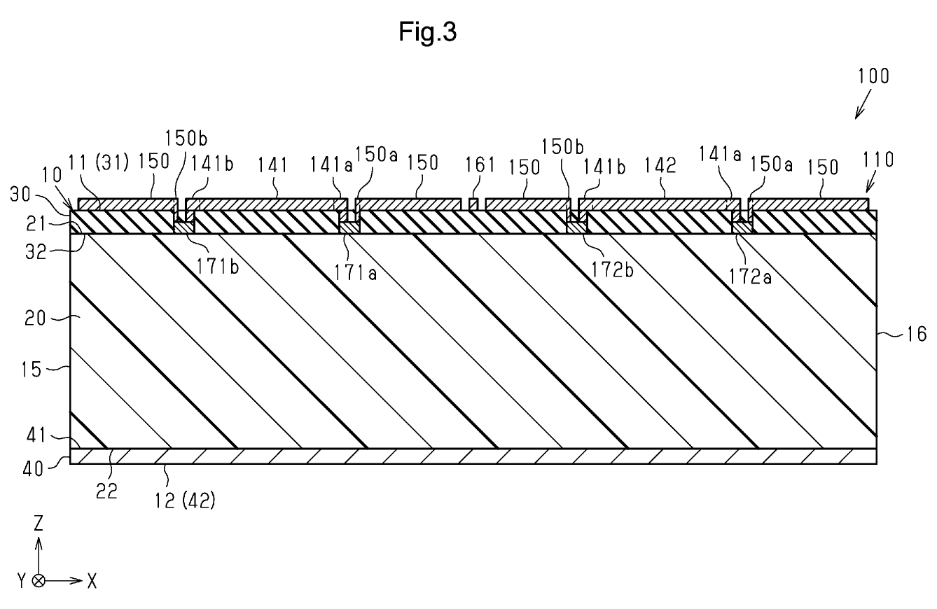

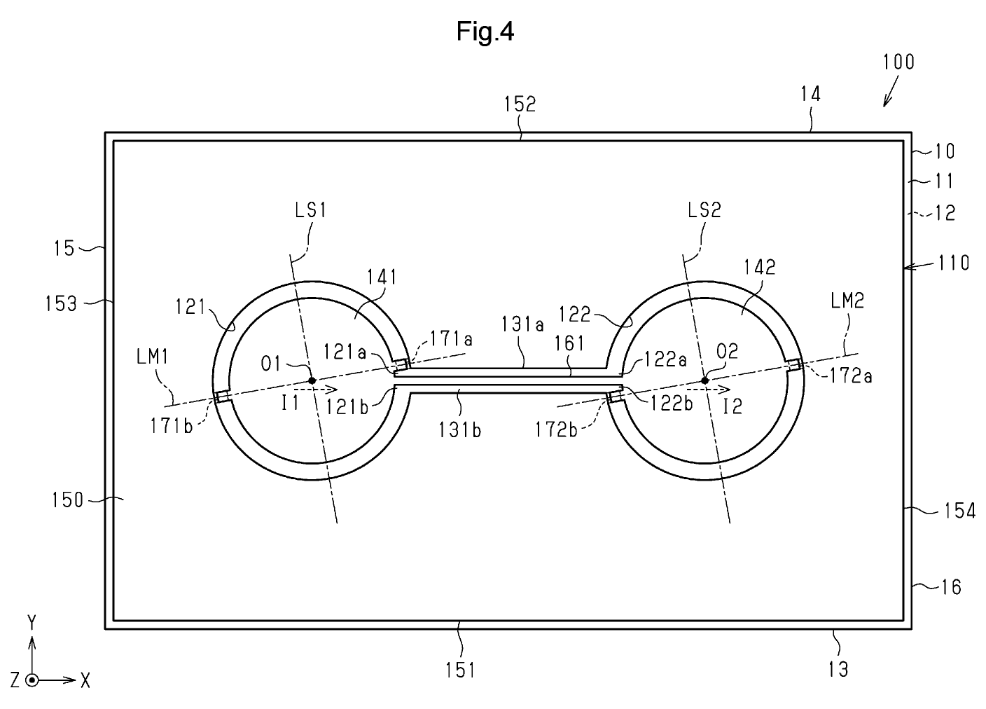

FIG. 1 is a schematic plan view of an exemplary terahertz device 100 in accordance with a first embodiment. FIG. 2 is a schematic perspective view of the terahertz device 100 illustrated in FIG. 1. FIG. 3 is a schematic cross-sectional view taken along line F3-F3 in FIG. 1. FIG. 4 is a schematic plan view showing some of the elements in the terahertz device 100 of FIG. 1 and illustrating the arrangement of slots 121 and 122, first electrodes 141 and 142, and active elements 171a, 171b, 172a, and 172b. In the present disclosure, the X-axis, Y-axis, and Z-axis are orthogonal to one another as shown in FIG. 1. The term “plan view” as used in this specification is a view of the terahertz device 100 taken in the Z-axis direction.

As shown in FIGS. 1 to 4, the terahertz device 100 includes a substrate 10. The substrate 10 has the form of a flat plate. As shown in FIG. 1, the substrate 10 has the form of a rectangular parallelepiped. In one example, the substrate 10 is quadrilateral and longer in the X-axis direction than in the Y-axis direction.

The substrate 10 includes a front surface 11, a back surface 12, and side surfaces 13, 14, 15, and 16. The front surface 11 and the back surface 12 are located at opposite sides of the substrate 10 in the Z-axis direction. Thus, the plan view is taken in a direction orthogonal to the front surface 11 of the substrate 10. In this specification, “orthogonal” is not meant to be strictly orthogonal and includes a generally orthogonal state allowing the advantages of the present embodiment to be obtained. The front surface 11 is rectangular in plan view. In the first embodiment, the side surfaces 13 to 16 of the substrate 10 are oriented in the X-axis direction or the Y-axis direction. The side surface 13 and the side surface 14 each extend along an XZ plane. The side surface 13 and the side surface 14 are located at opposite sides in the Y-axis direction. The side surface 15 and the side surface 16 each extend along a YZ plane. The side surface 15 and the side surface 16 are located at opposite sides in the X-axis direction. In the first embodiment, the X-axis direction corresponds to “the first direction,” and the Y-axis direction corresponds to “the second direction.”

As shown in FIGS. 2 and 3, the substrate 10 includes a semiconductor substrate 20 and an insulation layer 30, which is formed on the semiconductor substrate 20.

The semiconductor substrate 20 has the form of a flat plate. As shown in FIG. 1, the semiconductor substrate 20 is quadrilateral in plan view. In one example, the semiconductor substrate 20 is rectangular in plan view. The shape of the semiconductor substrate 20 in plan view may be square. The shape of the semiconductor substrate 20 in plan view does not have to be quadrilateral and may be circular, elliptic, or polygonal.

The semiconductor substrate 20 is formed from at least one semiconductor material selected from a group consisting of indium phosphorus (InP), gallium arsenide (GaAs), aluminum gallium arsenide (AlGaAs), indium gallium arsenide (InGaAs), indium gallium arsenide phosphide (InGaAsP), silicon (Si), silicon carbide (SiC), gallium nitride (GaN), and single-crystal aluminum nitride (AlN). In one example, the semiconductor substrate 20 is formed from a material including InP.

The semiconductor substrate 20 includes a substrate front surface 21 and a substrate back surface 22. The substrate front surface 21 and the substrate back surface 22 are located at opposite sides. The substrate front surface 21 faces the same direction as the front surface 11, and the substrate back surface 22 faces the same direction as the back surface 12. The semiconductor substrate 20 includes substrate side surfaces forming parts of the side surfaces 13 to 16. The substrate front surface 21 faces the same direction as the front surface 11. Thus, the Z-axis direction is orthogonal to the substrate front surface 21.

The terahertz device 100 includes the insulation layer 30 arranged on the semiconductor substrate 20. The substrate front surface 21 of the semiconductor substrate 20 is covered by the insulation layer 30. The insulation layer 30 is formed from an insulating material. The insulation layer 30 may be formed from a material including, for example, silicon oxide (SiO₂). In one example, the insulation layer 30 may be formed over the entire substrate front surface 21 of the semiconductor substrate 20.

The insulation layer 30 includes an insulation front surface 31 and an insulation back surface 32 at the opposite side of the insulation front surface 31. The insulation front surface 31 faces the same direction as the substrate front surface 21, and the insulation back surface 32 faces the same direction as the substrate back surface 22. The insulation front surface 31 forms the front surface 11. The insulation back surface 32 is in contact with the substrate front surface 21 of the semiconductor substrate 20. A further member such as an insulation layer may be arranged between the substrate front surface 21 of the semiconductor substrate 20 and the insulation layer 30. The insulation layer 30 includes insulation side surfaces forming parts of the side surfaces 13 to 16.

The terahertz device 100 includes a conductive layer 110 formed on the front surface 11 of the substrate 10. The conductive layer 110 is formed on parts of the front surface 11 of the substrate 10. The conductive layer 110 is formed from at least one metal material selected from a group consisting of gold (Au), silver (Ag), aluminum (Al), copper (Cu), titanium (Ti), titanium nitride (TiN), and platinum (Pt). The conductive layer 110 includes at least one of Au, Ag, Al, Cu, Ti, and Pt. In one example, the conductive layer 110 is formed from a material including Au. The conductive layer 110 is formed through, for example, sputtering. The conductive layer 110 may be formed by a stack of metal layers.

### Slots and Connecting Slits

The terahertz device 100 in accordance with the first embodiment may include two slots 121 and 122 formed in the conductive layer 110. The two slots 121 and 122 are separated from each other in the X-axis direction. The two slots 121 and 122 are aligned along the side surfaces 13 and 14 of the substrate 10. The direction in which the two slots 121 and 122 are aligned may be changed. The two slots 121 and 122 are annular.

In this specification, the term “annular” used to refer to the shape of a structure is not limited to a looped shape that is endless and continuous but also refers to a non-continuous looped shape including an opening (gap) such as the shape of the alphabetic letter “C.” Thus, the explicit description of a structure having an “annular shape that is closed” indicates a looped shape that is endless and continuous, while the explicit description of a structure having “an annular shape that is open” indicates a looped structure having an opening. Such an annular shape does not have to be a circle and may be a polygon including a right-angle corner or a rounded corner.

The slots 121 and 122 each have an annular shape that is open. The slots 121 and 122 respectively include first ends 121a and 122a and second ends 121b and 122b. The first ends 121a and 122a may respectively be separated from the second ends 121b and 122b in the Y-axis direction, which is orthogonal to the X-axis direction. The slots 121 and 122 are formed so that the first ends 121a and 122a are located relative to the second ends 121b and 122b in the same Y-axis direction. The slot 121, which is annular, is open toward the side surface 16 of the substrate 10 in the X-axis direction. The slot 122, which is annular, is open toward the side surface 15 of the substrate 10 in the X-axis direction. Further, the slots 121 and 122, which are annular, are open toward each other. In the first embodiment, the slot 121 corresponds to “the first slot,” and the slot 122 corresponds to “the second slot.”

The terahertz device 100 may further include two connecting slits 131a and 131b formed in the conductive layer 110. The two connecting slits 131a and 131b connect the two slots 121 and 122. The two connecting slits 131a and 131b each extend in the X-axis direction, in which the two slots 121 and 122 are aligned. The connecting slit 131a connects the first ends 121a and 122a of the two slots 121 and 122. The connecting slit 131b connects the second ends 121b and 122b of the two slots 121 and 122. In the first embodiment, the connecting slits 131a and 131b connect the two slots 121 and 122, which are adjacent to each other.

### First Electrode and Second Electrode

The conductive layer 110 includes the first electrodes 141 and 142 respectively defined in the slots 121 and 122. In one example, the first electrodes 141 and 142 are circular in plan view. The first electrodes 141 and 142 are separated from each other in the X-axis direction. Thus, the first electrodes 141 and 142 are aligned along the side surfaces 13 and 14 of the substrate 10.

The conductive layer 110 includes a second electrode 150 located outside the slots 121 and 122. In one example, the second electrode 150 is generally quadrilateral. The second electrode 150 includes a first side 151 and a second side 152, which are parallel to each other in plan view, and a third side 153 and a fourth side 154, which are orthogonal to the first side 151 and the second side 152. In one example, the second electrode 150 is rectangular and the first side 151 and the second side 152 are longer than the third side 153 and the fourth side 154. In one example, the second electrode 150 is arranged so that the first side 151 and the second side 152 extend in the X-axis direction in plan view. The second electrode 150 may be square so that the first side 151 and the second side 152 are equal in length to the third side 153 and the fourth side 154. Further, the second electrode 150 may be rectangular so that the third side 153 and the fourth side 154 are longer than the first side 151 and the second side 152.

### Connection Line

The conductive layer 110 includes a connection line 161 disposed in the connecting slits 131a and 131b. The connection line 161 extends along the connecting slits 131a and 131b in the X-axis direction. The connection line 161 has a first end connected to the first electrode 141 and a second end connected to the first electrode 142. The connection line 161 electrically connects the first electrodes 141 and 142 located inside the two slots 121 and 122, which are adjacent to each other in the X-axis direction. The connecting slits 131a and 131b insulate the connection line 161 from the second electrode 150. The connection line 161, which is insulated from the second electrode 150 by the connecting slits 131a and 131b, may be a coplanar waveguide (CPW).

### Active Elements

The terahertz device 100 includes active elements 171a and 171b, which are disposed in the slot 121, and active elements 172a and 172b, which are disposed in the slot 122. The slots 121 and 122 define the first electrodes 141 and 142 in the conductive layer 110. The terahertz device 100 includes the two active elements 171a and 171b, which are provided for the first electrode 141, and the two active elements 172a and 172b, which are provided for the first electrode 142. The conductive layer 110 includes the second electrode 150 located outside the slots 121 and 122. The terahertz device 100 includes the active elements 171a, 171b, 172a, and 172b disposed between the second electrode 150 and the first electrodes 141 and 142.

In the present disclosure, the active elements oscillate or detect electromagnetic waves. The active elements convert electromagnetic waves and electrical energy. Electromagnetic waves include either one of or both of light and radio waves. The active elements oscillate electromagnetic waves in a predetermined frequency band, for example, in the terahertz band (terahertz waves). In this case, the active elements may be referred to as terahertz elements that oscillate terahertz waves. Further, the active elements detect electromagnetic waves in a predetermined frequency band, for example, terahertz waves in the terahertz band. In this case, the active elements may be referred to as terahertz elements that receive terahertz waves. In one example, the frequency band of the terahertz waves ranges from 0.1 THz to 10 THz, inclusive.

In one example, the active elements 171a, 171b, 172a, and 172b may each be a resonant-tunneling diode (RTD). The active elements 171a, 171b, 172a, and 172b may each be a diode, other than an RTD, or a transistor. Examples of other active elements include a tunnel injection transit time (TUNNETT) diode, an impact ionization avalanche transit-time (IMPATT) diode, a GaAs field effect transistor (FET), a GaN FET, a high electron mobility transistor (HEMT), a heterojunction bipolar transistor (HBT), and a complementary metal–oxide–semiconductor (CMOS) FET.

The active elements 171a, 171b, 172a, and 172b are each quadrilateral in plan view. The active elements 171a, 171b, 172a, and 172b do not have to be quadrilateral in plan view and may be circular, elliptic, or polygonal.

The size of the slots 121 and 122 may be set in accordance with the wavelength of the electromagnetic waves generated or detected by the active elements 171a, 171b, 172a, and 172b, which are disposed in the slots 121 and 122. In one example, the size of the slot 121 (122) may be set so that the distance between the active elements 171a and 171b (172a and 172b) in the circumferential direction of the slot 121 (122) is close to or equal to one-half of an effective wavelength λg. The effective wavelength λg may be the wavelength of the terahertz waves propagated through the terahertz device 100.

The active elements 171a, 171b, 172a, and 172b are supplied with and oscillated by electrical energy to convert the supplied electrical energy into electromagnetic waves. This allows the active elements 171a, 171b, 172a, and 172b to oscillate electromagnetic waves in the desired frequency band. Further, the active elements 171a, 171b, 172a, and 172b receive electromagnetic waves and convert the electromagnetic waves into electrical energy. This allows the active elements 171a, 171b, 172a, and 172b to detect electromagnetic waves in the desired frequency band.

As shown in FIGS. 1 and 4, the active elements 171a and 171b are disposed at opposite sides of the first electrode 141 with respect to the center O1 of the slot 121 in plan view. In one example, the active element 171a is disposed at the first end 121a of the slot 121. The active element 171b is disposed in the slot 121 at the opposite side of the first end 121a with respect to the center O1 of the slot 121. The active elements 171a and 171b, which are disposed in the slot 121, are arranged in point symmetry about the center O1 of the slot 121. Further, the active elements 171a and 171b are disposed in the slot 121 at opposite sides of the first electrode 141 along a straight reference line LM1 extending through the center O1 of the slot 121. The center O1 of the slot 121 coincides with the center of the first electrode 141, which is encompassed by the slot 121. The straight reference line LM1 extends through the center of the first electrode 141. The active elements 171a and 171b are disposed in the slot 121 along the straight reference line LM1, which extends through the center of the first electrode 141. The straight reference line LM1 is inclined relative to the X-axis in plan view. Thus, the straight reference line LM1 is inclined relative to the connection line 161 in plan view. In the first embodiment, the active element 171a corresponds to “the first active element,” and the active element 171b corresponds to “the second active element.”

The active elements 172a and 172b are disposed at opposite sides of the first electrode 142 with respect to the center O2 of the slot 122 in plan view. In one example, the active element 172b is disposed at the second end 122b of the slot 122. The active element 172a is disposed in the slot 122 at the opposite side of the second end 122b with respect to the center O2 of the slot 122. The active elements 172a and 172b, which are disposed in the slot 122, are arranged in point symmetry about the center O2 of the slot 122. Further, the active elements 172a and 172b are disposed in the slot 122 at opposite sides of the first electrode 142 along a reference line LM2 extending through the center O2 of the slot 122. The center O2 of the slot 122 coincides with the center of the first electrode 142, which is encompassed by the slot 122. The reference line LM2 extends through the center of the first electrode 142. The active elements 172a and 172b are disposed in the slot 122 along the reference line LM2, which extends through the center of the first electrode 142. The reference line LM2 is inclined relative to the X-axis in plan view. Thus, the reference line LM2 is inclined relative to the connection line 161 in plan view. In the first embodiment, the active element 172b corresponds to “the third active element,” and the active element 172a corresponds to “the fourth active element.”

In one example, the straight reference line LM1 of the slot 121 is parallel to the straight reference line LM2 of the slot 122. The inclination of the reference lines LM1 and LM2 relative to the connection line 161 is equal to the angle between the connection line 161 and the straight reference lines LM1 and LM2.

The active elements 171a and 171b are connected to the first electrode 141 and the second electrode 150 to perform oscillation in a state in which their phases are inverted with respect to each other (antiphase). The active elements 171a and 171b are connected in parallel between the first electrode 141 and the second electrode 150.

The active elements 172a and 172b are connected to the first electrode 142 and the second electrode 150 to perform oscillation in a state in which their phases are inverted with respect to each other (antiphase). The active elements 172a and 172b are connected in parallel between the first electrode 142 and the second electrode 150.

The wall surfaces of the conductive layer 110 defining the slot 121, in which the active elements 171a and 171b are disposed, that is, the first electrode 141 and the part of the second electrode 150 surrounding the first electrode 141, form a slot antenna 121R. The wall surfaces of the conductive layer 110 defining the slot 122, in which the active elements 172a and 172b are disposed, that is, the first electrode 142 and the part of the second electrode 150 surrounding the first electrode 142, form a slot antenna 122R.

The terahertz device 100 in accordance with the first embodiment includes the two slot antennas 121R and 122R that are aligned in the X-axis direction. The first electrodes 141 and 142, which form the two slot antennas 121R and 122R, are electrically connected by the connection line 161. This allows the terahertz device 100 in accordance with the first embodiment to operate the two slot antennas 121R and 122R in synchronization. The terahertz device 100 in accordance with the first embodiment emits electromagnetic waves with a higher output than, for example, a terahertz device including only one active element or a terahertz device including only one slot antenna. This allows the terahertz device 100 in accordance with the first embodiment to have improved characteristics.

In the terahertz device 100 in accordance with the first embodiment, it is preferable that current flow in the same direction between the two slot antennas 121R and 122R to improve the efficiency for emission or detection of electromagnetic waves by the two slot antennas 121R and 122R. In FIG. 4, the arrows in broken lines indicate examples of current I1 flowing between the active elements 171a and 171b, which are connected to the first electrode 141, and current I2 flowing between the active elements 172a and 172b, which are connected to the first electrode 141. The direction of currents I1 and I2 change in accordance with a drive signal provided to the active elements 171a, 171b, 172a, and 172b.

In order to have the currents I1 and I2 flow in the same direction, it is preferable that the active element 171a and 172a be operated in the same phase and that the active elements 171b and 172b be operated in phases inverted from the active elements 171a and 172a. In other words, it is preferable that the terahertz device 100 be configured so that the active element 171a, which is disposed at the first end 121a of the slot 121, be operated in phases inverted from the active element 172b, which is disposed at the second end 122b of the slot 122. The connection line 161 may have a length adjusted so that the phase of the active element 171a is inverted from the phase of the active element 172b. The length of the connection line 161 may be close to or equal to (2n-1)/2 (where n is an integer of 1 or greater) of the effective wavelength λg in the terahertz device 100. In one example, the length of the connection line 161 may be one-half of the effective wavelength λg (λg/2) in the terahertz device 100. The connection line 161 is set so that current flows in the same direction in the two first electrodes 141 and 142, which are connected by the connection line 161. Further, the length of the connection line 161 is set so that the active element 171a and the active element 172b, which are located at opposite ends, are operated in inverted phases.

### Resistive Elements

As shown in FIG. 1, the terahertz device 100 may include resistive elements R1 and R2 connected to each of the first electrodes 141 and 142. The resistive elements R1 and R2 are disposed outside the slots 121 and 122. The resistive elements R1 and R2 are disposed overlapping the second electrode 150.

The resistive elements R1 and R2 are disposed at opposite sides of each of the first electrodes 141 and 142. The resistive elements R1 and R2 are arranged in point symmetry about the centers O1 and O2 of the corresponding slots 121 and 122. The resistive elements R1 and R2 are connected in parallel to the active elements 171a, 171b, 172a, and 172b, which are disposed in the slots 121 and 122. The resistive elements R1 and R2 suppress parasitic oscillation. The resistive elements R1 and R2 stabilize oscillation at the active elements 171a, 171b, 172a, and 172b.

The resistive elements R1 and R2 may be connected to imaginary short-circuit points of the first electrodes 141 and 142. An imaginary short-circuit point is a pseudo-short circuit point where the terahertz waves generated by the active elements 171a, 171b, 172a, and 172b, which oscillate in inverted phases, have a relatively low electric field strength. The electric field generated by the active elements 171a, 171b, 172a, and 172b, which oscillate in inverted phases, are superimposed.

Referring to FIG. 4, the electric field strength is relatively low between the two active elements 171a and 171b and between the two active elements 172a and 172b along a straight auxiliary line LS1, which extends through the center O1 of the slot 121 and is orthogonal to the straight reference line LM1 connecting the active elements 171a and 171b, and along a straight auxiliary line LS2, which extends through the center O2 of the slot 122 and is orthogonal to the straight reference line LM2 connecting the active elements 172a and 172b. The resistive elements R1 and R2 may be connected to the first electrodes 141 and 142 in correspondence with the straight auxiliary lines LS1 and LS2.

### First Electrode Pads and Second Electrode Pads

As shown in FIGS. 1 and 2, the conductive layer 110 includes two first electrode pads 181 and 182. The two first electrode pads 181 and 182 are arranged in correspondence with the two first electrodes 141 and 142. The quantity of the first electrode pads 181 and 182 may be changed. In one example, the terahertz device 100 may include one first electrode pad 181. The single first electrode pad 181 may be connected to one of the first electrode 141 and the first electrode 142 or both of the first electrode 141 and the first electrode 142.

The first electrode pads 181 and 182 are separated from the second electrode 150. The second electrode 150 includes recesses 1551 and 1552, which extend from the second side 152 toward the first electrodes 141 and 142. The first electrode pads 181 and 182 are respectively disposed in the recesses 1551 and 1552.

The first electrode pads 181 and 182 are electrically connected by interconnections 51 and 52 to the first electrodes 141 and 142. The interconnections 51 and 52 may each include a lower wire 61 and vias 62 and 63. The lower wire 61 is disposed in the insulation layer 30. The lower wire 61 may be located between the semiconductor substrate 20 and the conductive layer 110. The via 62 electrically connects the lower wire 61 to the corresponding one of the first electrode pads 181 and 182. The via 63 electrically connects the lower wire 61 to the corresponding one of the first electrodes 141 and 142. The interconnections 51 and 52 may be respectively connected to the imaginary short-circuit points of the first electrodes 141 and 142. In one example, the via 63 is connected to the imaginary short-circuit point of the first electrode 141 in the slot 121 or the first electrode 142 of the slot 122. This suppresses the leakage of electromagnetic waves to the interconnections 51 and 52.

The lower wire 61 and the vias 62 and 63 are formed from at least one metal material selected from a group consisting of Au, Ag, Al, Cu, Ti, TiN, and Pt. The lower wire 61 and the vias 62 and 63 include at least one of Au, Ag, Al, Cu, Ti, and Pt. In one example, the lower wire 61 and the vias 62 and 63 are formed from a material including Au.

The second electrode pads 181b and 182b of the first electrodes 141 and 142 are arranged in parts of the second electrode 150 at the opposite side of the first electrode pads 181 and 182. The second electrode pads 181b and 182b are arranged along the first side 151 of the second electrode 150 and separated from each other in the X-axis direction.

### Reflective Layer

The terahertz device 100 includes a reflective layer 40 arranged on the back surface 12 of the substrate 10. The reflective layer 40 is in contact with the back surface 12 of the substrate 10. The reflective layer 40 includes a reflective front surface 41 and a reflective back surface 42 at the opposite side of the reflective front surface 41. The reflective front surface 41 faces the same direction as the substrate front surface 21. The reflective back surface 42 faces the same direction as the substrate back surface 22. The reflective layer 40 has a thickness that allows for the reflection of electromagnetic waves generated or detected by the second active elements 171b and 172b and the first active elements 171a and 172a. The reflective layer 40 may overlap the slots 121 and 122 in plan view. In one example, the reflective layer 40 covers the entire back surface 12 of the substrate 10.

The reflective layer 40 is formed by a metal layer arranged on the back surface 12 of the substrate 10. The reflective layer 40 is formed from at least one metal material selected from a group consisting of Au, Ag, Al, Cu, Ti, TiN, and Pt. The reflective layer 40 includes at least one of Au, Ag, Al, Cu, Ti, and Pt. In one example, the reflective layer 40 is formed from a material including Au. The reflective layer 40 may be formed from the same material as the conductive layer 110. The reflective layer 40 may be formed through, for example, sputtering. The reflective layer 40 may be formed by a stack of metal layers.

### Detail of First Active Element and Second Active Element

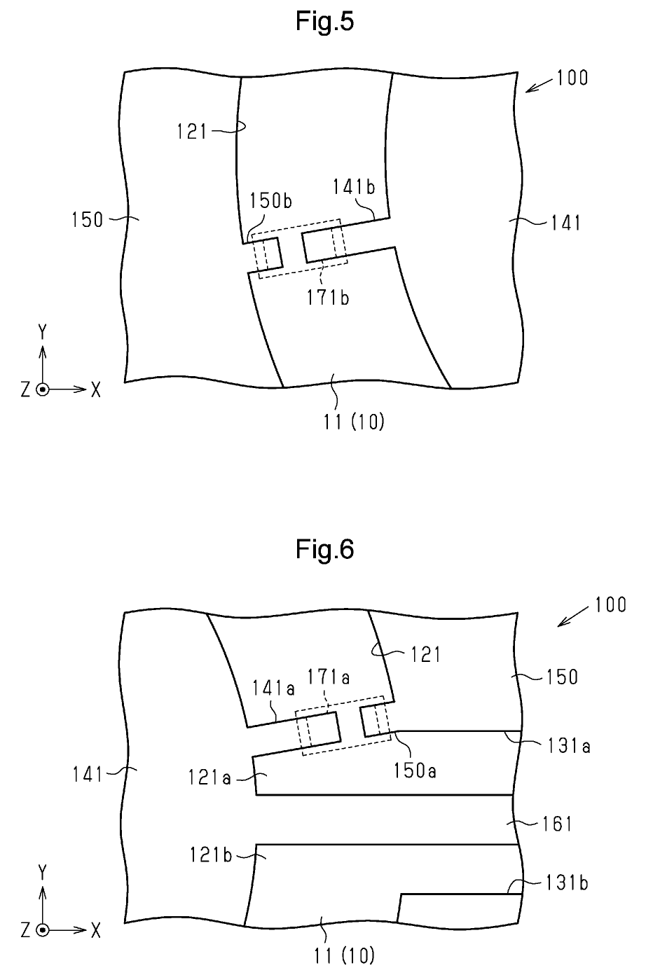

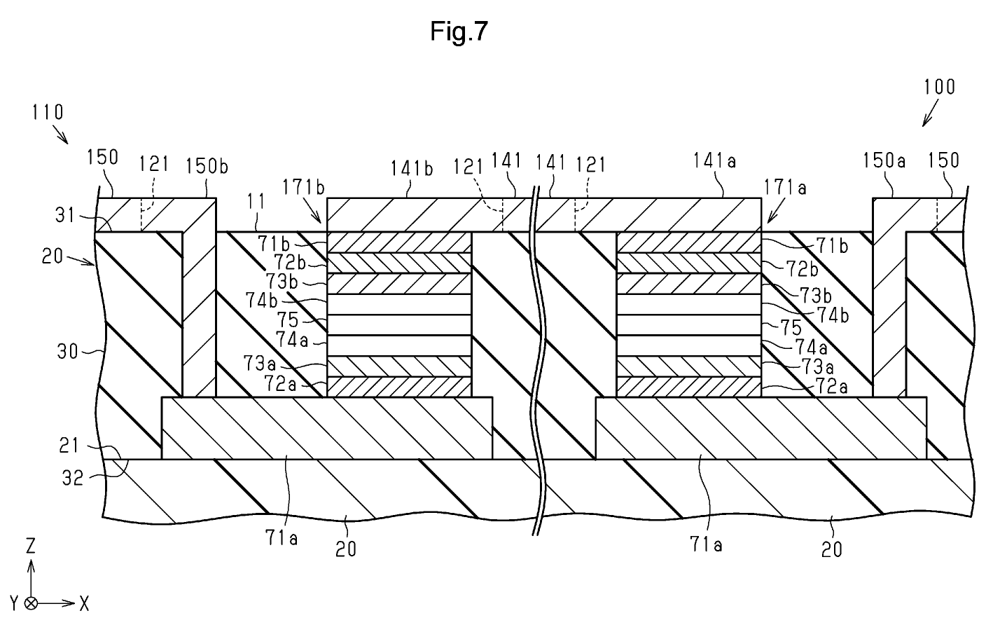

FIG. 5 is a schematic plan view enlarging part of the terahertz device 100 illustrated in FIG. 1 and showing the arrangement of the second active element 171b. FIG. 6 is a schematic plan view enlarging part of the terahertz device 100 illustrated in FIG. 1 and showing the arrangement of the first active element 171a. FIG. 7 is a schematic cross-sectional view of the second active element 171b and the first active element 171a.

One example of a structure including the first active element 171a and the second active element 171b will now be described.

As shown in FIG. 7, the first active element 171a and the second active element 171b are located between the first electrode 141 and the semiconductor substrate 20 in the Z-axis direction.

A semiconductor layer 71a is arranged on the substrate front surface 21 of the semiconductor substrate 20. In one example, the semiconductor layer 71a is quadrilateral in plan view. The semiconductor layer 71a is formed from, for example, GaInAs. The semiconductor layer 71a is doped with an n-type impurity at a high concentration. A GaInAs layer 72a is formed on the semiconductor layer 71a. The GaInAs layer 72a is doped with an n-type impurity. The GaInAs layer 72a has a lower n-type impurity concentration than the semiconductor layer 71a. A GaInAs layer 73a is formed on the GaInAs layer 72a. The GaInAs layer 73a is not doped with an impurity.

An AlAs layer 74a is formed on the GaInAs layer 73a. An InGaAs layer 75 is formed on the AlAs layer 74a. The InGaAs layer 75 is not doped with an impurity. An AlAs layer 74b is formed on the InGaAs layer 75. The AlAs layer 74a, the InGaAs layer 75, and the AlAs layer 74b form a resonant tunneling structure.

A GaInAs layer 73b that is not doped with an impurity is formed on the AlAs layer 74b. A GaInAs layer 72b that is not doped with an n-type impurity is formed on the GaInAs layer 73b. A GaInAs layer 71b that is doped with n-type impurity at a high concentration is formed on the GaInAs layer 72b. Thus, the GaInAs layer 71b has a higher n-type impurity concentration than the GaInAs layer 72b.

The specific structures of the first active element 171a and the second active element 171b may be changed as long as electromagnetic waves can be generated and/or detected. In other words, the first active element 171a and the second active element 171b may have any structure as long as electromagnetic waves in the terahertz band can be at least oscillated or detected.

With respect to the second active element 171b, a connecting portion 150b, which extends from the second electrode 150 toward the semiconductor layer 71a, is electrically connected to the semiconductor layer 71a. A connecting portion 141b, which extends from the first electrode 141 and contacts the upper surface of the GaInAs layer 71b, is electrically connected to the GaInAs layer 71b. In this manner, the second active element 171b is connected between the second electrode 150 and the first electrode 141.

With respect to the first active element 171a, a connecting portion 141a, which extends from the first electrode 141 and contacts the upper surface of the GaInAs layer 71b, is electrically connected to the GaInAs layer 71b. A connecting portion 150a, which extends from the second electrode 150 toward the semiconductor layer 71a, is electrically connected to the semiconductor layer 71a. In this manner, the first active element 171a is connected between the first electrode 141 and the second electrode 150.

The first active element 172a shown in FIGS. 1, 3, and 4 has the same structure as the first active element 171a shown in FIGS. 6 and 7 and is connected to the first electrode 142 and the second electrode 150. The second active element 172b has the same structure as the second active element 171b shown in FIGS. 5 and 7 and is connected to the first electrode 142 and the second electrode 150. Thus, the structures of the first active element 172a and the second active element 172b are not illustrated in the drawings and will not be described.

### Detail of Resistive Elements

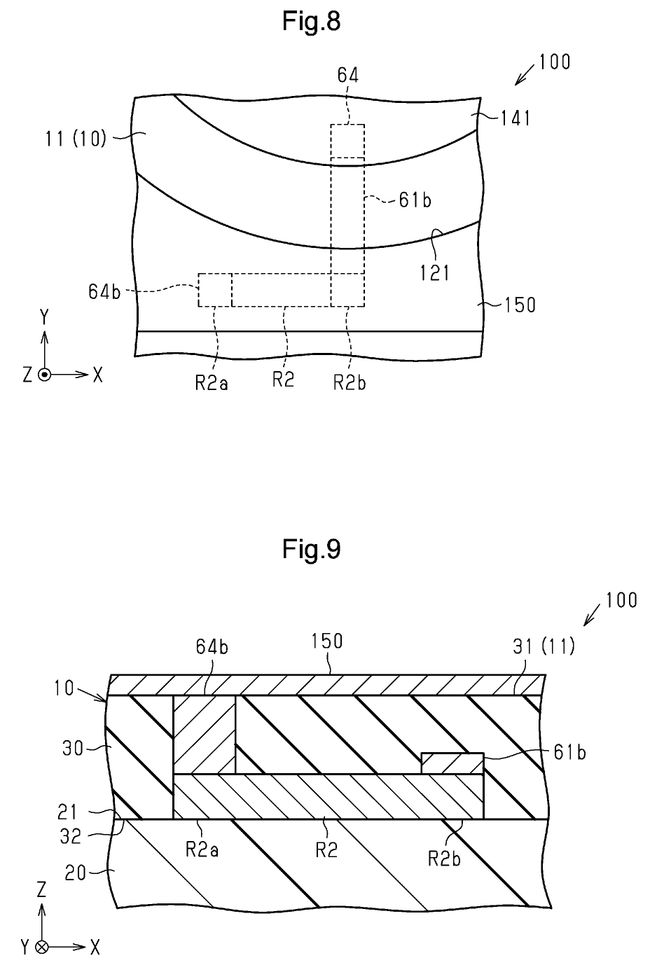

FIG. 8 is a schematic plan view enlarging part of the terahertz device 100 illustrated in FIG. 1 and showing the arrangement of the resistive element R2. FIG. 9 is a schematic cross-sectional view of the resistive element R2 illustrated in FIG. 8.

As shown in FIG. 9, the resistive element R2 is located between the semiconductor substrate 20 and the second electrode 150. The resistive element R2 is arranged on the substrate front surface 21 of the semiconductor substrate 20. In one example, the resistive element R2 is quadrilateral in plan view. The resistive element R2 is formed by a semiconductor layer doped with an n-type impurity at a high concentration. One example of the semiconductor layer is a GaInAs layer.

The resistive element R2 includes a first end R2a and a second end R2b, opposite to the first end R2a. The first end R2a is electrically connected to the second electrode 150 by a via 64b formed on the resistive element R2. The via 64b is formed from at least one metal material selected from a group consisting of Au, Ag, Al, Cu, Ti, TiN, and Pt. The via 64b includes at least one of Au, Ag, Al, Cu, Ti, and Pt. In one example, the via 64b is formed from a material including Au.

The second end R2b of the resistive element R2 is connected to the lower wire 61b. The lower wire 61b is disposed in the insulation layer 30 in the Z-axis direction. The lower wire 61b is located between the insulation front surface 31 and the insulation back surface 32 in the Z-axis direction. In one example, the insulation layer 30 may include a first insulation film, which is formed on the semiconductor substrate 20, and a second insulation film, which is formed on the first insulation film. The first insulation film may have, for example, the same thickness as the resistive element R2. The lower wire 61b may be formed on the first insulation film. The insulation layer 30 may include three or more insulation films. The lower wire 61b is formed from at least one metal material selected from a group consisting of Au, Ag, Al, Cu, Ti, TiN, and Pt. The lower wire 61b includes at least one of Au, Ag, Al, Cu, Ti, and Pt. In one example, the lower wire 61b is formed from a material including Au.

As shown in FIG. 8, the lower wire 61b is electrically connected to the first electrode 141 by a via 64. In this manner, the resistive element R2 is connected between the first electrode 141 and the second electrode 150.

As shown in FIG. 1, the resistive element R1 is electrically connected to the first electrode 141 by the lower wire 61 and the via 63. Further, the resistive element R1 is electrically connected to the second electrode 150 by the via 63b. In this manner, the resistive element R1 is connected between the first electrode 141 and the second electrode 150. The resistive elements R1 and R2 for the first electrode 142 are connected in the same manner as the resistive elements R1 and R2 for the first electrode 141.

### Operation

The operation of the terahertz device 100 in accordance with the first embodiment will now be described.

The slots 121 and 122 are annular. The conductive layer 110 includes the first electrodes 141 and 142, which are defined in the slots 121 and 122, the connection line 161, which is disposed in the connecting slits 131a and 131b to electrically connect the first electrodes 141 and 142, which are located inside the two adjacent slots 121 and 122, and the second electrode 150, which is located outside the slots 121 and 122. The connecting slits 131a and 131b connect the slots 121 and 122 and insulate the connection line 161 from the second electrode 150. The active elements 171a and 171b are disposed in the first electrode 141 at opposite sides of the first electrode 141 with respect to the center O1 of the slot 121, in a plan view taken from a direction orthogonal to the front surface 11. The active elements 172a and 172b are disposed in the first electrode 142 at opposite sides of the first electrode 142 with respect to the center O2 of the slot 122, in the plan view.

The terahertz device 100 in accordance with the first embodiment includes the two slot antennas 121R and 122R that are aligned in the X-axis direction. Thus, the terahertz device 100 in accordance with the first embodiment emits electromagnetic waves with a higher output than, for example, a terahertz device including only one active element or a terahertz device including only one slot antenna. This allows the terahertz device 100 in accordance with the first embodiment to have improved characteristics.

The first electrodes 141 and 142, which form the two slot antennas 121R and 122R, are electrically connected by the connection line 161. This allows the terahertz device 100 in accordance with the first embodiment to operate the two slot antennas 121R and 122R in synchronization. The terahertz device 100 in accordance with the first embodiment emits electromagnetic waves with a higher output than, for example, a terahertz device including only one active element or a terahertz device including only one slot antenna.

(1-2) The first electrodes 141 and 142, which are defined by the slots 121 and 122, are electrically connected by the connection line 161. Thus, the terahertz device 100 in accordance with the first embodiment allows current to flow in the same direction through the first electrodes 141 and 142, which are defined by the two slots 121 and 122.

(1-3) The length of the connection line 161 is adjusted so that the active element 171a of the slot 121 and the active element 172b of the slot 122 have inverted phases. This allows current to flow in the same direction through the first electrodes 141 and 142.

(1-4) The resistive elements R1 and R2 are disposed at opposite sides of each of the first electrodes 141 and 142. The resistive elements R1 and R2 are arranged in point symmetry about the centers O1 and O2 of the corresponding slots 121 and 122. The resistive elements R1 and R2 are connected in parallel to the active elements 171a, 171b, 172a, and 172b, which are disposed in the slots 121 and 122. The resistive elements R1 and R2 suppress parasitic oscillation.

(1-5) The resistive elements R1 and R2 may be connected to imaginary short-circuit points of the first electrodes 141 and 142. This suppresses the leakage of electromagnetic waves to the resistive elements R1 and R2, the lower wires 61b, which connect the resistive elements R1 and R2 to the first electrodes 141 and 142, and the vias 64.

(1-6) The interconnections 51 and 52, which connect the first electrode pads 181 and 182 to the first electrodes 141 and 142, may connect the first electrodes 141 and 142 to the imaginary short-circuit point. This suppresses the leakage of electromagnetic waves to the interconnections 51 and 52.

### Advantages

### The first embodiment has the advantages described below.

(1-1) The terahertz device 100 includes the substrate 10, which has the front surface 11 and the back surface 12, the conductive layer 110, which is formed on the front surface 11, the slots 121 and 122, which are formed in the conductive layer 110, the connecting slits 131a and 131b, which are formed in the conductive layer 110, and the active elements 171a, 171b, 172a, and 172b, which are disposed in the slots 121 and 122.

The slots 121 and 122 are annular. The conductive layer 110 includes the first electrodes 141 and 142, which are defined in the slots 121 and 122, the connection line 161, which is disposed in the connecting slits 131a and 131b to electrically connect the first electrodes 141 and 142 located inside the two adjacent slots 121 and 122, and the second electrode 150, which is located outside the slots 121 and 122.

The connecting slits 131a and 131b connect the slots 121 and 122 and insulate the connection line 161 from the second electrode 150. The active elements 171a and 171b are disposed in the first electrode 141 at opposite sides of the first electrode 141 with respect to the center O1 of the slot 121, in a plan view taken from a direction orthogonal to the front surface 11. The active elements 172a and 172b are disposed in the first electrode 142 at opposite sides of the first electrode 142 with respect to the center O2 of the slot 122 in the plan view.

The terahertz device 100 in accordance with the first embodiment emits electromagnetic waves with a higher output than, for example, a terahertz device including only one active element or a terahertz device including only one slot antenna. This allows the terahertz device 100 in accordance with the first embodiment to have improved characteristics.

1-2 The first electrodes 141 and 142, which are defined by the slots 121 and 122, are electrically connected by the connection line 161. Thus, the terahertz device 100 in accordance with the first embodiment allows current to flow in the same direction through the first electrodes 141 and 142, which are defined by the two slots 121 and 122. This allows the terahertz device 100 in accordance with the first embodiment to emit electromagnetic waves with a high output.

1-3 The length of the connection line 161 is adjusted so that the active element 171a of the slot 121 and the active element 172b of the slot 122 have inverted phases. The difference in phase reduces mutual cancellation of electromagnetic waves. This allows the terahertz device 100 in accordance with the first embodiment to emit electromagnetic waves with a high output.

1-4 The resistive elements R1 and R2 are disposed at opposite sides of each of the first electrodes 141 and 142. The resistive elements R1 and R2 are arranged in point symmetry about the centers O1 and O2 of the corresponding slots 121 and 122. The resistive elements R1 and R2 are connected in parallel to the active elements 171a, 171b, 172a, and 172b, which are disposed in the slots 121 and 122. The resistive elements R1 and R2 suppress parasitic oscillation. The resistive elements R1 and R2 stabilize oscillation at the active elements 171a, 171b, 172a, and 172b.

1-5 The resistive elements R1 and R2 may be connected to imaginary short-circuit points of the first electrodes 141 and 142. This suppresses the leakage of electromagnetic waves to the resistive elements R1 and R2, the lower wires 61b, which connect the resistive elements R1 and R2 to the first electrodes 141 and 142, and the vias 64. Thus, the terahertz device 100 emits electromagnetic waves efficiently.

1-6 The interconnections 51 and 52, which connect the first electrode pads 181 and 182 to the first electrodes 141 and 142, may connect the first electrodes 141 and 142 to imaginary short-circuit points. This suppresses the leakage of electromagnetic waves to the interconnections 51 and 52. Thus, the terahertz device 100 emits electromagnetic waves efficiently.

### Second Embodiment

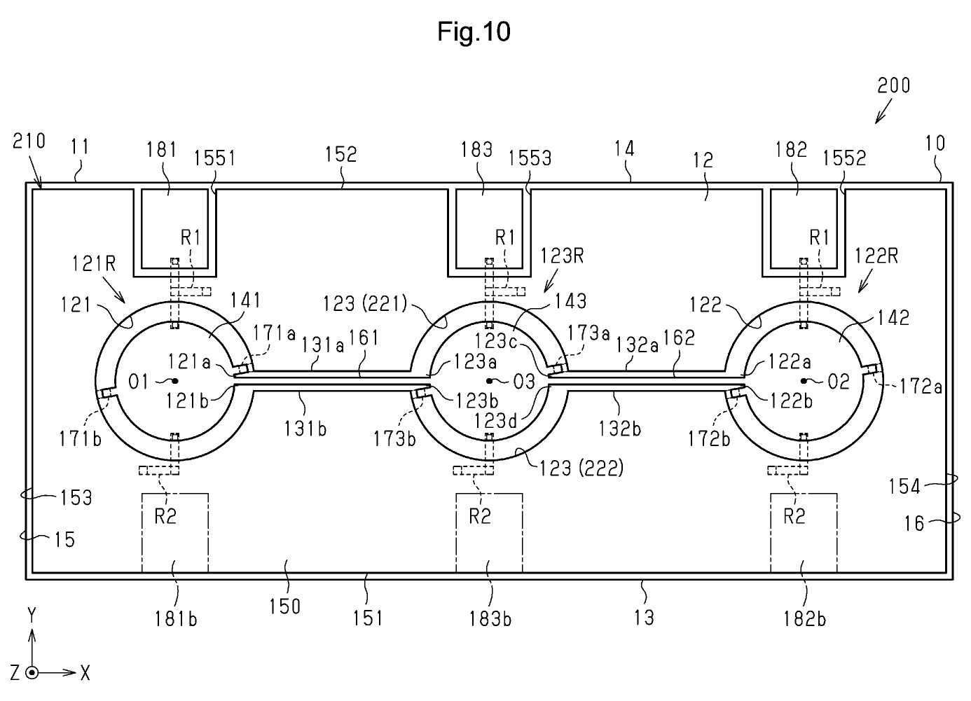

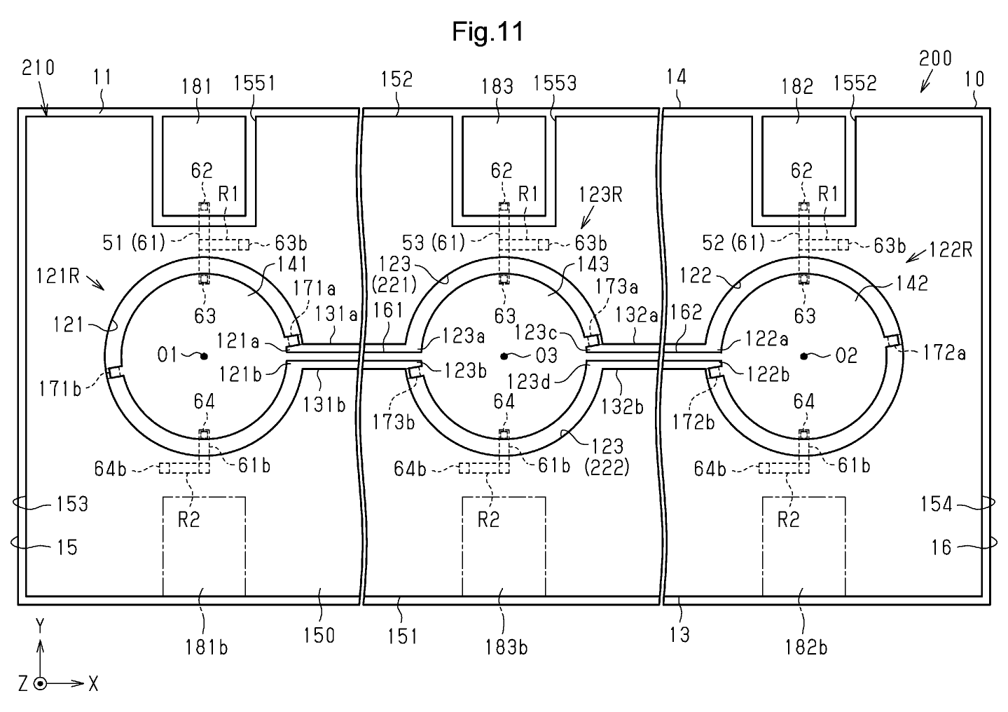

With reference to FIGS. 10 and 11, a terahertz device 200 in accordance with a second embodiment will now be described.

In the second embodiment, same reference numerals are given to those components that are the same as the corresponding components of the first embodiment. Such components will not be described in detail.

The terahertz device 200 in accordance with the second embodiment differs from the terahertz device 100 in accordance with the first embodiment in that it includes three slots 121, 122, and 123, and connecting slits 131a, 131b, 132a, and 132b, which connect the slots 121, 122, and 123. Thus, the description of the second embodiment will focus on such differences.

FIG. 10 is a schematic plan view of an exemplary terahertz device 200 in accordance with the second embodiment. FIG. 11 is a schematic plan view enlarging the part where the slots 121, 122, and 123 are illustrated in FIG. 10.

### Slots and Connecting Slits

The terahertz device 200 in accordance with the second embodiment may include three slots 121, 122, and 123 that are formed in a conductive layer 210. The three slots 121, 122, and 123 are separated from one another in the X-axis direction. The three slots 121, 122, and 123 are aligned along the side surfaces 13 and 14 of the substrate 10. The direction in which the three slots 121, 122, and 123 are aligned may be changed. The three slots 121, 122, and 123 are annular. The slots 121, 122, and 123 have an annular shape that is open and respectively include first ends 121a, 122a, and 123a and second ends 121b, 122b, and 123b. The slots 121, 122, and 123 are arranged so that the first ends 121a, 122a, and 123a and the second ends 121b, 122b, and 123b are aligned in the Y-axis direction.

### First Slot

The slot 121 has an open annular shape. The slot 121 includes the first end 121a and the second end 121b. The first end 121a may be separated from the second end 121b in the Y-axis direction that is orthogonal to the X-axis direction. Thus, the slot 121 has an open annular shape in which the first end 121a is separated from the second end 121b in the Y-axis direction.

### Third Slot

The slot 122 has an open annular shape. The slot 122 includes the first end 122a and the second end 122b. The first end 122a may be separated from the second end 122b in the Y-axis direction that is orthogonal to the X-axis direction. Thus, the slot 122 has an open annular shape in which the first end 122a is separated from the second end 122b in the Y-axis direction.

### Second Slot

The slot 123 includes a first part 221 and a second part 222, which are semicircular. The first part 221 is separated from the second part 222 in the Y-axis direction. The first part 221 is semicircular and open toward the second part 222. The second part 222 is semicircular and open toward the first part 221. Thus, the first part 221 and the second part 222 open the annular slot 123 at opposite sides in the X-axis direction.

The first part 221 includes the first end 123a of the slot 123 and a third end 123c at the side opposite to the first end 123a. The first end 123a of the first part 221 is separated from the first end 121a of the slot 121 in the X-axis direction. Thus, the first part 221 includes the first end 123a that is separated from the first end 121a of the slot 121 in the X-axis direction. The third end 123c of the first part 221 is separated from the first end 122a of the slot 122 in the X-axis direction. Thus, the first part 221 includes the third end 123c that is separated from the first end 122a of the slot 122 in the X-axis direction.

The second part 222 includes the second end 123b of the slot 123 and a fourth end 123d at the opposite side of the second end 123b. The second end 123b of the second part 222 is separated from the second end 121b of the slot 121 in the X-axis direction. Thus, the second part 222 includes the second end 123b that is separated from the second end 121b of the slot 121 in the X-axis direction. The fourth end 123d of the second part 222 is separated from the second end 122b of the slot 122 in the X-axis direction. Thus, the second part 222 includes the fourth end 123d that is separated from the second end 122b of the slot 122 in the X-axis direction.

The first part 221 and the second part 222 may be shaped identically. The first part 221 is equal in length to the second part 222 in the circumferential direction of the slot 123. The first part 221 and the second part 222 may be arranged in symmetry about the center O3 of the slot 123. Thus, the first end 123a of the first part 221 and the fourth end 123d of the second part 222 are located on opposite sides of the center O3 of the slot 123. The first end 123a of the first part 221 and the fourth end 123d of the second part 222 lie along a straight line extending through the center O3 of the slot 123. Further, the third end 123c of the first part 221 and the second end 123b of the second part 222 are located on opposite sides of the center O3 of the slot 123. Thus, the third end 123c of the first part 221 and the second end 123b of the second part 222 lie along a straight line extending through the center O3 of the slot 123. The slot 123 includes two ends arranged next to each other in the Y-axis direction at each of the two opposite sides in the X-axis direction.

The first part 221 and the second part 222 open the annular slot 123, which is located at the central part in the X-axis direction, at opposite sides in the X-axis direction. Thus, in the slot 123, the first end 123a and the second end 123b are located toward the slot 121 in the X-axis direction, and the third end 123c and the fourth end 123d are located toward the slot 122 in the X-axis direction.

### Connecting Slits

The terahertz device 200 includes four connecting slits 131a, 131b, 132a, and 132b formed in the conductive layer 210. The connecting slits 131a, 131b, 132a, and 132b extend in the X-axis direction, in which the slots 121, 123, and 122 are aligned. The connecting slit 131a connects the first end 121a of the slot 121 and the first end 123a of the slot 123. The connecting slit 131b connects the second end 121b of the slot 121 and the second end 123b of the slot 123. The connecting slit 132a connects the third end 123c of the slot 123 and the first end 122a of the slot 122. The connecting slit 132b connects the fourth end 123d of the slot 123 and the second end 122b of the slot 122.

In the second embodiment, with regard to the two slots 121 and 123, the slot 121 corresponds to “the first slot,” and the slot 123 corresponds to “the second slot.” Further, with regard to the two slots 123 and 122, the third end 123c of the slot 123, which is connected to the first end 122a of the slot 122, may act as the first end of the slot 123 in relation to the slot 122. The fourth end 123d of the slot 123, which is connected to the second end 122b of the slot 122, may act as the second end of the slot 123 in relation to the slot 122. Thus, the slot 123 corresponds to “the first slot,” and the slot 122 corresponds to “the second slot.”

### First Electrode and Second Electrode

The conductive layer 210 includes first electrodes 141, 143, and 142, which are respectively defined by the slots 121, 123, and 122. In one example, the first electrodes 141, 143, and 142 are circular in plan view. The first electrodes 141, 143, and 142 are separated from one another in the X-axis direction. Thus, the first electrodes 141, 143, and 142 are aligned along the side surfaces 13 and 14 of the substrate 10.

### Connection Lines

The conductive layer 210 includes a connection line 161, which is disposed in the connecting slits 131a and 131b, and a connection line 162, which is disposed in the connecting slits 132a and 132b.

The connection line 161 extends along the connecting slits 131a and 131b in the X-axis direction. The connection line 161 has a first end connected to the first electrode 141 and a second end connected to the first electrode 143. The connection line 161 electrically connects the first electrodes 141 and 143 that are respectively located inside the two slots 121 and 123, which are adjacent to each other in the X-axis direction. The connecting slits 131a and 131b insulate the connection line 161 from the second electrode 150. The connection line 161, which is insulated from the second electrode 150 by the connecting slits 131a and 131b, may be a coplanar waveguide (CPW).

The connection line 162 extends along the connecting slits 132a and 132b in the X-axis direction. The connection line 162 has a first end connected to the first electrode 143 and a second end connected to the first electrode 142. The connection line 162 electrically connects the first electrodes 143 and 142 that are respectively located inside the two slots 123 and 122, which are adjacent to each other in the X-axis direction. The connecting slits 132a and 132b insulate the connection line 162 from the second electrode 150. The connection line 162, which is insulated from the second electrode 150 by the connecting slits 132a and 132b, may be a coplanar waveguide (CPW).

In the terahertz device 200 in accordance with the second embodiment, it is preferable that current flow in the same direction through the first electrodes 141, 143, and 142, which are defined by the three slots 121, 123, and 122. The length of the connection line 161 may be adjusted so that the active element 171a of the slot 121 and an active element 173b of the slot 123 have inverted phases. The length of the connection line 162 may be adjusted so that an active element 173a of the slot 123 and the active element 172b of the slot 122 have inverted phases. The length of each of the connection lines 161 and 162 may be close to or equal to (2n-1)/2 (where n is an integer of 1 or greater) of the effective wavelength λg in the terahertz device 200. In one example, the length may be one-half of the effective wavelength λg (λg/2) in the terahertz device 200. The connection line 161 is set so that current flows in the same direction in the two first electrodes 141 and 143, which are connected by the connection line 161. The connection line 162 is set so that current flows in the same direction in the two first electrodes 143 and 142, which are connected by the connection line 162.

### Active Elements

The terahertz device 200 includes the active elements 171a, 171b, 173a, 173b, 172a, and 172b.

The active elements 171a and 171b are disposed in the slot 121. The active elements 172a and 172b are disposed in the slot 122.

The active elements 173a and 173b are disposed in the slot 123. The active elements 173a and 173b are disposed in the slot 123 at opposite sides of the first electrode 143 with respect to the center O3 of the slot 123. The active element 173a is disposed in the third end 123c of the first part 221. The active element 173b is disposed in the second end 123b of the second part 222. The second end 123b of the second part 222 may be referred to as the second end of the slot 123. Thus, the active element 173b is disposed in the second end of the slot 123. Further, the active element 173b corresponds to “the third active element” disposed in the second end of the slot 123, which acts as the second slot in relation to the slot 121. The active element 173a corresponds to the “fourth active element” disposed at the opposite side of the second end with respect to the center O3 of the slot 123.

The active element 173a is disposed in the first end of the slot 123, which acts as the first slot, in relation to the slot 122, which acts as the second slot. Thus, the active element 173a corresponds to the “first active element” in relation to the slot 122. The active element 173b corresponds to the “second active element” in relation to the slot 122. The active elements 172a and 172b of the slot 122 respectively correspond to “the fourth active element” and the “third active element” in relation to the slot 123.

The active elements 173a and 173b may be, for example, RTDs in the same manner as the active elements 171a and 171b. The active elements 173a and 173b may each be a diode, other than an RTD, or a transistor. Examples of other active elements include, for example, a TUNNETT diode, an IMPATT diode, a GaAs FET, a GaN FET, an HEMT, an HBT, and a CMOS FET.

The wall surfaces of the conductive layer 210 defining the slot 121, in which the active elements 171a and 171b are disposed, that is, the first electrode 141 and the part of the second electrode 150 surrounding the first electrode 141, form a slot antenna 121R. The wall surfaces of the conductive layer 210 defining the slot 122, in which the active elements 172a and 172b are disposed, that is, the first electrode 142 and the part of the second electrode 150 surrounding the first electrode 142, form a slot antenna 122R. The wall surfaces of the conductive layer 210 defining the slot 123, in which the active elements 173a and 173b are disposed, that is, the first electrode 141 and the part of the second electrode 150 surrounding the first electrode 141, form a slot antenna 123R.

The terahertz device 200 in accordance with the second embodiment includes three slot antennas 121R, 123R, and 122R aligned in the X-axis direction. The first electrodes 141, 143, and 142, which form the three slot antennas 121R, 123R, and 122R, are electrically connected by the connection lines 161 and 162. This allows the terahertz device 200 in accordance with the second embodiment to operate the slot antennas 121R, 123R, and 122R in synchronization. The terahertz device 200 in accordance with the second embodiment emits electromagnetic waves with a higher output than, for example, a terahertz device including only one active element or a terahertz device including only one slot antenna.

### First Electrode Pads and Second Electrode Pads

As shown in FIGS. 10 and 11, the conductive layer 210 includes three first electrode pads 181, 183, and 182. The three first electrode pads 181, 183, and 182 are arranged in correspondence with the three first electrodes 141, 143, and 142. The quantity of the first electrode pads may be changed.

The first electrodes 141, 143, and 142 are separated from the second electrode 150. The second electrode 150 includes recesses 1551, 1553, and 1552, which extend from the second side 152 toward the first electrodes 141, 143, and 142. The first electrode pads 181, 183, and 182 are respectively disposed in the recesses 1551, 1553, and 1552.

As shown in FIG. 11, the first electrode pads 181, 183, and 182 are electrically connected to the first electrodes 141, 143, and 142 by interconnections 51, 53, and 52. The interconnection 53, which has the same structure as the interconnections 51 and 52, may include the lower wire 61 and the vias 62 and 63. The lower wire 61 of the interconnection 53 is electrically connected to the first electrode pad 183 by the via 62. Further, the lower wire 61 of the interconnection 53 is electrically connected to the first electrode 143 by the via 63.

Second electrode pads 181b, 183b, and 182b are respectively arranged at opposite sides of the first electrode pads 181, 183, and 182 with respect to the first electrodes 141, 143, and 142. The second electrode pads 181b, 183b, and 182b are arranged along the first side 151 of the second electrode 150 and separated from one another in the X-axis direction.

### Resistive Elements

The terahertz device 200 may include the resistive elements R1 and R2 connected to each of the first electrodes 141, 143, and 142. The first electrode 143 is connected to a first end of the resistive element R1 by the lower wire 61 of the interconnection 53, and a second end of the resistive element R1 is electrically connected to the second electrode 150 by the via 63b. Further, the first electrode 143 is connected to a first end of the resistive element R2 by the via 64 and the lower wire 61b, and a second end of the resistive element R2 may be electrically connected to the second electrode 150 by the via 64b.

### Advantages

### The second embodiment has the advantages described below.

2-1 The terahertz device 200 in accordance with the second embodiment has the same advantages as the terahertz device 100 in accordance with the first embodiment.

2-2 The terahertz device 200 in accordance with the second embodiment includes the three slots 121, 123, and 122 and the active elements 171a, 171b, 173a, 173b, 172a, and 172b, which are disposed in the slots 121, 123, and 122. Thus, the terahertz device 200 in accordance with the second embodiment has a higher output than the terahertz device 100 in accordance with the first embodiment.

2-2 The first electrodes 141 and 143, which are defined by the slots 121 and 123, are electrically connected by the connection line 161. The first electrodes 143 and 142, which are defined by the slots 123 and 122, are electrically connected by the connection line 162. Thus, the terahertz device 200 in accordance with the second embodiment allows current to flow in the same direction through the first electrodes 141, 143, and 142, which are defined by the three slots 121, 123, and 122. This allows the terahertz device 200 in accordance with the second embodiment to emit electromagnetic waves with a high output.

2-3 The length of the connection line 161 is adjusted so that the active element 171a of the slot 121 and the active element 173b of the slot 123 have inverted phases. The length of the connection line 162 is adjusted so that the active element 173a of the slot 123 and the active element 172b of the slot 122 have inverted phases. The difference in phase reduces mutual cancellation of electromagnetic waves. This allows the terahertz device 200 in accordance with the second embodiment to emit electromagnetic waves with a high output.

### Third Embodiment

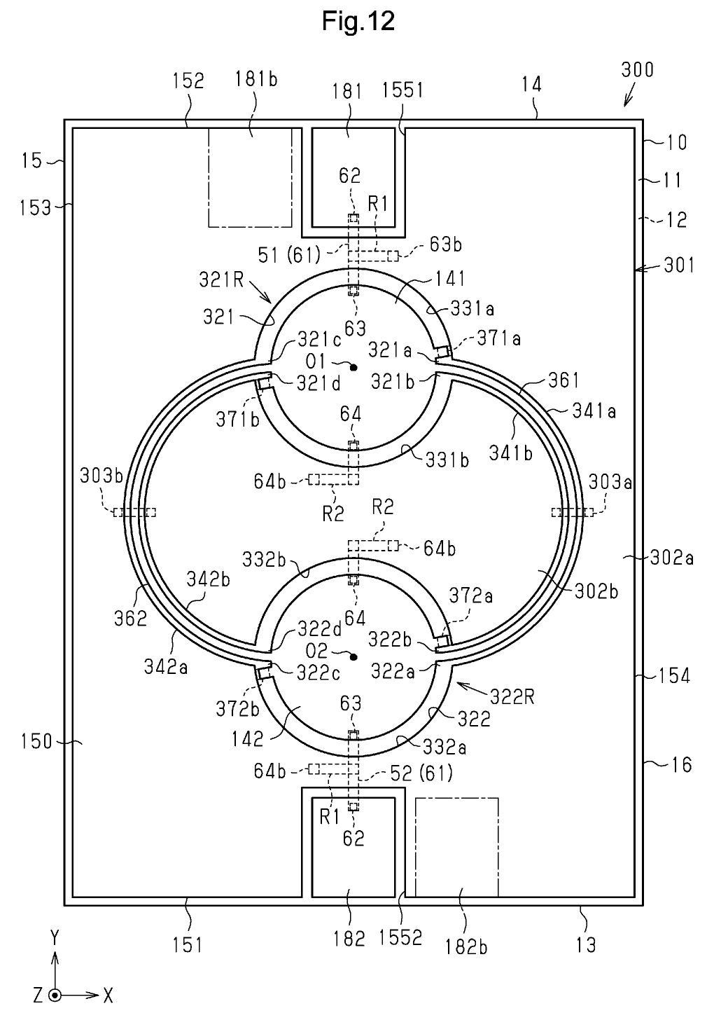

With reference to FIG. 12, a terahertz device 300 in accordance with a third embodiment will now be described.

In the third embodiment, same reference numerals are given to those components that are the same as the corresponding components of the first embodiment. Such components will not be described in detail.

The terahertz device 300 in accordance with the third embodiment differs from the terahertz device 100 in accordance with the first embodiment in the arrangement of two slots 321 and 322, and in connecting slits 341a, 341b, 342a, and 342b connecting the slots 321 and 322. Thus, the description of the third embodiment will focus on such differences.

### Schematic Configuration of Terahertz Device

FIG. 12 is a schematic plan view of an exemplary terahertz device 300 in accordance with the third embodiment.

As shown in FIG. 12, the terahertz device 300 includes the substrate 10. The substrate 10 may be quadrilateral and longer in the Y-axis direction than in the X-axis direction.

### Slots and Connecting Slits

The terahertz device 300 in accordance with the third embodiment may include two slots 321 and 322 formed in a conductive layer 301. The two slots 321 and 322 are separated from each other in the Y-axis direction. The two slots 321 and 322 are aligned along the side surface 15 and 16 of the substrate 10. The direction in which the two slots 321 and 322 are aligned may be changed. The two slots 321 and 322 are annular. The slots 321 and 322 have an annular shape that is open and respectively include first ends 321a and 322a and second ends 321b and 322b. The slots 321 and 322 are arranged so that the first ends 321a and 322a, and the second ends 321b and 322b are aligned in the Y-axis direction.

### First Slot

The slot 321 includes a first part 331a and a second part 331b, which are semicircular. The first part 331a and the second part 331b are separated in the Y-axis direction. The first part 331a and the second part 331b are arranged at opposite sides of the slot 322. The first part 331a is semicircular and open toward the second part 331b. The second part 331b is semicircular and open toward the first part 331a. Thus, the first part 331a and the second part 331b open the annular slot 321 at opposite sides in the X-axis direction.

The first part 331a includes a first end 321a of the slot 321 and a third end 321c at the opposite side of the first end 321a. The second part 331b includes the second end 321b of the slot 321 and a fourth end 321d at the opposite side of the second end 321b. The first part 331a and the second part 331b may be shaped identically. The first part 331a is equal in length to the second part 331b in the circumferential direction of the slot 321. The first part 331a and the second part 331b may be arranged in symmetry about the center O1 of the slot 321. Thus, the first end 321a of the first part 331a and the fourth end 321d of the second part 331b are located on opposite sides of the center O1 of the slot 321. Further, the first end 321a of the first part 331a and the fourth end 321d of the second part 331b lie along a straight line extending through the center O1 of the slot 321. The third end 321c of the first part 331a and the second end 321b of the second part 331b are located on opposite sides of the center O1 of the slot 321. The third end 321c of the first part 331a and the second end 321b of the second part 331b lie along a straight line extending through the center O1 of the slot 321. Thus, the slot 321 includes two ends arranged next to each other in the Y-axis direction at each of the two opposite sides in the X-axis direction.

### Second Slot

The slot 322 includes a third part 332a and a fourth part 332b, which are semicircular. The third part 332a and the fourth part 332b are separated in the Y-axis direction. The third part 332a is arranged at the side of the fourth part 332b opposite to the second part 331b of the slot 321. The third part 332a is semicircular and open toward the fourth part 332b. The fourth part 332b is semicircular and open toward the third part 332a. Thus, the third part 332a and the fourth part 332b open the annular slot 322 at opposite sides in the X-axis direction.

The third part 332a includes the first end 322a of the slot 322 and a third end 322c at the side opposite to the first end 322a. The fourth part 332b includes the second end 322b of the slot 322 and a fourth end 322d at the opposite side of the second end 322b. The third part 332a and the fourth part 332b may be shaped identically. The third part 332a is equal in length to the fourth part 332b in the circumferential direction of the slot 322. The third part 332a and the fourth part 332b may be arranged in symmetry about the center O2 of the slot 322. Thus, the first end 322a of the third part 332a and the fourth end 322d of the fourth part 332b are located on opposite sides of the center O2 of the slot 322. The first end 322a of the third part 332a and the fourth end 322d of the fourth part 332b lie along a straight line extending through the center O2 of the slot 322. Further, the third end 322c of the third part 332a and the second end 322b of the fourth part 332b are located on opposite sides of the center O2 of the slot 322. The third end 322c of the third part 332a and the second end 322b of the fourth part 332b lie along a straight line extending through the center O2 of the slot 322. Thus, the slot 322 includes two ends arranged next to each other in the Y-axis direction at each of the two opposite sides in the X-axis direction.

The slots 321 and 322 each have an annular shape that is open. The slots 321 and 322 are separated in the Y-axis direction that is orthogonal to the X-axis direction in which the open parts are oriented.

### Connecting Slits

The terahertz device 300 includes four connecting slits 341a, 341b, 342a, and 342b formed in the conductive layer 301.

The connecting slits 341a, 341b, 342a, and 342b each extend outward from the slots 321 and 322 in the X-axis direction as viewed in the Y-axis direction. The connecting slits 341a, 341b, 342a, and 342b each connect the slots 321 and 322.

The first connecting slit 341a connects the first end 321a of the first part 331a and the first end 322a of the third part 332a. Thus, the first connecting slit 341a connects the first end 321a of the slot 321 and the first end 322a of the slot 322. The second connecting slit 341b connects the second end 321b of the second part 331b and the second end 322b of the fourth part 332b. Thus, the second connecting slit 341b connects the second end 321b of the slot 321 and the second end 322b of the slot 322. The connecting slits 341a and 341b are semicircular.

The third connecting slit 342a connects the third end 321c of the first part 331a and the third end 322c of the third part 332a. Thus, the third connecting slit 342a connects the third end 321c of the slot 321 and the third end 322c of the slot 322. The fourth connecting slit 342b connects the fourth end 321d of the second part 331b and the fourth end 322d of the fourth part 332b. Thus, the fourth connecting slit 342b connects the fourth end 321d of the slot 321 and the fourth end 322d of the slot 322. The connecting slits 342a and 342b are semicircular.

### First Electrodes and Second Electrode

The conductive layer 301 includes first electrodes 141 and 142, which are respectively defined by the slots 321 and 322. In one example, the first electrodes 141 and 142 are circular in plan view. The first electrodes 141 and 142 are separated from each other in the Y-axis direction.

The second connecting slit 341b connects the second end 321b of the second part 331b and the second end 322b of the fourth part 332b. The fourth connecting slit 342b connects the fourth end 321d of the second part 331b and the fourth end 322d of the fourth part 332b. Thus, the second part 331b, the fourth part 332b, and the connecting slits 341b and 342b define an electrode portion 302b in the conductive layer 301. The second electrode 150 includes a peripheral portion 302a surrounding the slots 321 and 322 and the connecting slits 341a and 342a. The electrode portion 302b is electrically connected to the peripheral portion 302a by interconnections 303a and 303b. The electrode portion 302b and the peripheral portion 302a form the second electrode 150.

The interconnections 303a and 303b may each include, for example, a lower wire, a via, and the like. The lower wire of the interconnection 303a intersects the connecting slits 341a and 341b and a connection line 361. The lower wire of the interconnection 303b intersects the connecting slits 342a and 342b and a connection line 362. The interconnections 303a and 303b may extend across the connecting slits 341a, 341b, 342a, and 342b and the connection lines 361 and 362. In one example, the connecting slits 341a, 341b, 342a, and 342b and the connection lines 361 and 362 may be partially covered by an insulation layer. Further, the interconnections 303a and 303b may be formed on the insulation layer to electrically connect the electrode portion 302b and the peripheral portion 302a, which form the second electrode 150.

### Connection Lines

The conductive layer 301 includes the connection line 361, which is disposed in the connecting slits 341a and 341b, and the connection line 362, which is disposed in the connecting slits 342a and 342b. In one example, the connection line 361 is arcuate and extends along the connecting slits 341a and 341b. In one example, the connection line 362 is arcuate and extends along the connecting slits 342a and 342b.

### Active Elements

The terahertz device 300 includes active elements 371a, 371b, 372a, and 372b.

The active elements 371a and 371b are disposed in the slot 321. The active elements 371a and 371b are disposed in the slot 321 at opposite sides of the first electrode 141 with respect to the center O1 of the slot 321. The active element 371a is disposed in the first end 321a of the first part 331a. The active element 371b is disposed in the fourth end 321d of the second part 331b. The first end 321a of the first part 331a and the fourth end 321d of the second part 331b are located on opposite sides of the center O1 of the slot 321. Thus, the active elements 371a and 371b are disposed in the slot 321 and 322 along a straight reference line extending through the center O1 of the slot 321.

The active elements 372a and 372b are disposed in the slot 322. The active elements 372a and 372b are disposed in the slot 322 at opposite sides of the first electrode 142 with respect to the center O2 of the slot 322. The active element 372a is disposed in the second end 322b of the fourth part 332b. The active element 372b is disposed in the third end 322c of the third part 332a. The second end 322b of the fourth part 332b and the third end 322c of the third part 332a are located at opposite sides of the center O2 of the slot 322. Thus, the active elements 372a and 372b are disposed in the slots 321 and 322 along a straight reference line extending through the center O2 of the slot 322.

The active elements 371a, 371b, 372a, and 372b may be, for example, RTDs. The active elements 371a, 371b, 372a, and 372b may each be a diode, other than an RTD, or a transistor. Examples of other active elements include, for example, a TUNNETT diode, an IMPATT diode, a GaAs FET, a GaN FET, an HEMT, an HBT, and a CMOS FET.

The active elements 371a and 371b are connected in parallel to the first electrode 141 and the second electrode 150. The active elements 372a and 372b are connected in parallel to the first electrode 142 and the second electrode 150. The connection lines 361 and 362 may be formed so that the active element 371a and the active element 372a are operated in the same phase, and the active element 371b and the active element 372b are operated in the same phase.

The wall surfaces of the conductive layer 301 defining the slot 321, in which the active elements 371a and 371b are disposed, that is, the first electrode 141 and the part of the second electrode 150 surrounding the first electrode 141, form a slot antenna 321R. The wall surfaces of the conductive layer 301 defining the slot 322, in which the active elements 372a and 372b are disposed, that is, the first electrode 142 and the part of the second electrode 150 surrounding the first electrode 142, form a slot antenna 322R.

The terahertz device 300 in accordance with the third embodiment includes the two slot antennas 321R and 322R that are aligned in the Y-axis direction. The first electrodes 141 and 142, which form the two slot antennas 321R and 322R, are electrically connected by the connection lines 361 and 362. This allows the terahertz device 300 in accordance with the third embodiment to operate the two slot antennas 321R and 322R in synchronization. The terahertz device 300 in accordance with the third embodiment emits electromagnetic waves with a higher output than, for example, a terahertz device including only one active element or a terahertz device including only one slot antenna.

### First Electrode Pads and Second Electrode Pads

The conductive layer 301 includes two first electrode pads 181 and 182. The two first electrode pads 181 and 182 are arranged in correspondence with the two first electrodes 141 and 142. The quantity of the first electrode pads 181 and 182 may be changed.

The first electrode pads 181 and 182 are separated from the second electrode 150. The second electrode 150 includes a recess 1551, which extends from the second side 152 toward the first electrode 141, and a recess 1552, which extends from the first side 151 toward the first electrode 142. The first electrode pads 181 and 182 are respectively disposed in the recesses 1551 and 1552.

Second electrode pads 181b and 182b are respectively arranged next to the first electrode pads 181 and 182 in the X-axis direction. The second electrode pad 181b is arranged next to the first electrode pad 181 along the second side 152 of the second electrode 150. The second electrode pad 182b is arranged next to the first electrode pad 182 along the first side 151 of the second electrode 150. The quantity of the second electrode pads 181b and 182b may be changed.

### Operation

The operation of the terahertz device 300 in accordance with the third embodiment will now be described.

The lengths of the connection lines 361 and 362 may be adjusted so that the active element 371a of the slot 321 and the active element 372a of the slot 322 are operated in the same phase, and the active element 371b of the slot 321 and the active element 372b of the slot 322 are operated in the same phase. The length of each of the connection lines 361 and 362 may be close to or equal to an integer multiple of the effective wavelength λg (n×λg, where n is an integer of 1 or greater) in the terahertz device 300. In one example, the length of each of the connection lines 361 and 362 may be equal to the effective wavelength λg in the terahertz device 300. The connection lines 361 and 362 are set so that current flows in the same direction in the two first electrodes 141 and 142, which are connected by the connection lines 361 and 362. Thus, the length of each of the connection lines 361 and 362 is set so that the active elements 371a and 371b, which are located at opposite ends of the connection line 361 are operated in the same phase, and the active elements 372a and 372b, which are located at opposite ends of the connection line 362, are operated in the same phase.

### Advantages

### The third embodiment has the advantages described below.

3-1 In the terahertz device 300 in accordance with the third embodiment, the annular slots 321 and 322 that are open in the X-axis direction are separated from each other in the Y-axis direction. The slots 321 and 322, which are defined by the first electrodes 141 and 142, are connected to each other by the connection lines 361 and 362. This allows the terahertz device 300, in which the slots 321 and 322 and the first electrodes 141 and 142 are arranged in this manner, to have high output.

3-2 The first electrodes 141 and 142 are connected to each other by the connection lines 361 and 362. The first electrodes 141 and 142, which are connected to each other, operate the active elements 371a, 371b, 372a, and 372b, which are disposed in the slots 321 and 322, in synchronization, increasing the output.

3-3 The length of each of the connection lines 361 and 362 is adjusted so that the active element 371a and the active element 372a have the same phase, and the active element 371b and the active element 372b have the same phase. This allows current to flow in the same direction through the first electrodes 141 and 142. Thus, the terahertz device 300 in accordance with the third embodiment to emit electromagnetic waves with a high output.

### Fourth Embodiment

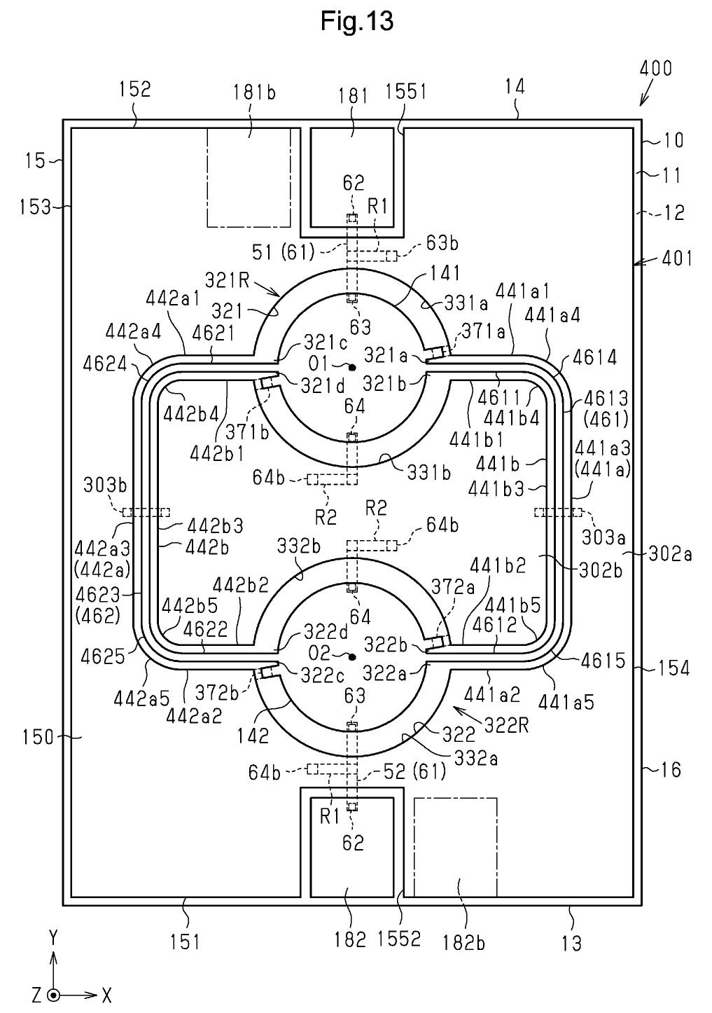

With reference to FIG. 13, a terahertz device 400 in accordance with a fourth embodiment will now be described.

In the fourth embodiment, same reference numerals are given to those components that are the same as the corresponding components of the third embodiment. Such components will not be described in detail.

The terahertz device 400 in accordance with the fourth embodiment differs from the terahertz device 300 in accordance with the third embodiment in the shape of connecting slits 441a, 441b, 442a, and 442b and connection lines 461 and 462. Thus, the description of the fourth embodiment will focus on such differences from the third embodiment.

FIG. 13 is a schematic plan view of an exemplary terahertz device 400 in accordance with the fourth embodiment.

The terahertz device 400 in accordance with the fourth embodiment may include the two slots 321 and 322, which are formed in a conductive layer 401, and the connecting slits 441a, 441b, 442a, and 442b, which connect the two slots 321 and 322. The connecting slits 441a, 441b, 442a, and 442b are generally U-shaped as viewed in the Z-axis direction. The connection lines 461 and 462 are also generally U-shaped as viewed in the Z-axis direction.

The connecting slit 441a includes a first straight portion 441a1 and a second straight portion 441a2, which extend in the X-axis direction, a third straight portion 441a3, which extends in the Y-axis direction, a first connecting portion 441a4, which connects the first straight portion 441a1 and the third straight portion 441a3, and a second connecting portion 441a5, which connects the second straight portion 441a2 and the third straight portion 441a3. The first straight portion 441a1 is connected to the first end 321a of the first part 331a, and the second straight portion 441a2 is connected to the first end 322a of the third part 332a.

The connecting slit 441b includes a first straight portion 441b1 and a second straight portion 441b2, which extend in the X-axis direction, a third straight portion 441b3, which extends in the Y-axis direction, a first connecting portion 441b4, which connects the first straight portion 441b1 and the third straight portion 441b3, and a second connecting portion 441b5, which connects the second straight portion 441b2 and the third straight portion 441b3. The first straight portion 441b1 is connected to the second end 321b of the second part 331b, and the second straight portion 441b2 is connected to the second end 322b of the fourth part 332b.

The connecting slit 442a includes a first straight portion 442a1 and a second straight portion 442a2, which extend in the X-axis direction, a third straight portion 442a3, which extends in the Y-axis direction, a first connecting portion 442a4, which connects the first straight portion 442a1 and the third straight portion 442a3, and a second connecting portion 442a5, which connects the second straight portion 442a2 and the third straight portion 442a3. The first straight portion 442a1 is connected to the third end 321c of the first part 331a, and the second straight portion 442a2 is connected to the third end 322c of the third part 332a.

The connecting slit 442b includes a first straight portion 442b1 and a second straight portion 442b2, which extend in the X-axis direction, a third straight portion 442b3, which extends in the Y-axis direction, a first connecting portion 442b4, which connects the first straight portion 442b1 and the third straight portion 442b3, and a second connecting portion 442b5, which connects the second straight portion 442b2 and the third straight portion 442b3. The first straight portion 442b1 is connected to the fourth end 321d of the second part 331b, and the second straight portion 442b2 is connected to the fourth end 322d of the fourth part 332b.

The connection line 461 includes a first connection line 4611 and a second connection line 4612, which extend in the X-axis direction, a third connection line 4613, which extends in the Y-axis direction, a first connecting portion 4614, which connects the first connection line 4611 and the third connection line 4613, and a second connecting portion 4615, which connects the second connection line 4612 and the third connection line 4613.

The connection line 462 includes a first connection line 4621 and a second connection line 4622, which extend in the X-axis direction, a third connection line 4623, which extends in the Y-axis direction, a first connecting portion 4624, which connects the first connection line 4621 and the third connection line 4623, and a second connecting portion 4625, which connects the second connection line 4622 and the third connection line 4623.

### Advantages

### The fourth embodiment has the advantages described below.

4-1 The terahertz device 400 in accordance with the fourth embodiment has the same advantages as the terahertz device 300 in accordance with the third embodiment.

### Fifth Embodiment

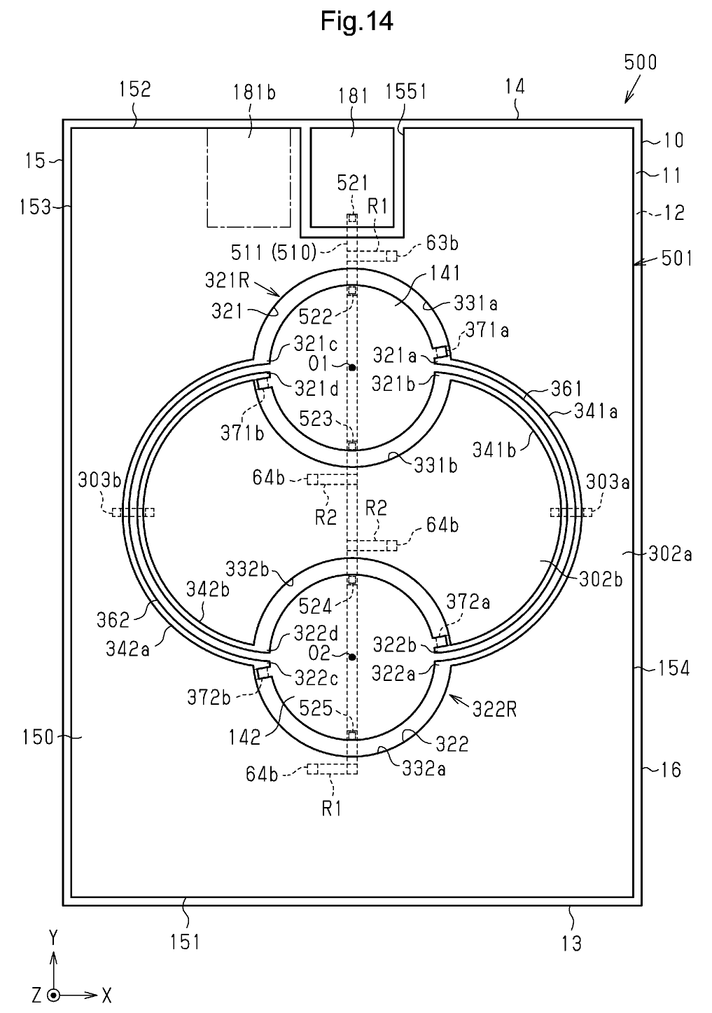

With reference to FIG. 14, a terahertz device 500 in accordance with a fifth embodiment will now be described.

In the fifth embodiment, same reference numerals are given to those components that are the same as the corresponding components of the third embodiment. Such components will not be described in detail.

The terahertz device 500 in accordance with the fourth embodiment differs from the terahertz device 300 in accordance with the third embodiment in the first electrode pad 181 and its connection. Thus, the description of the fifth embodiment will focus on such differences from the third embodiment.

FIG. 14 is a schematic plan view of an exemplary terahertz device 500 in accordance with the fifth embodiment.

As shown in FIG. 14, a conductive layer 501 includes a single first electrode pad 181 and a single second electrode pad 181b for the two first electrodes 141 and 142.

The first electrode pad 181 is aligned with the first electrodes 141 and 142. The first electrode pad 181 is electrically connected by an interconnection 510 to the first electrodes 141 and 142.

The interconnection 510 may include a lower wire 511 and vias 521, 522, 523, 524, and 525. The lower wire 511 extends in the Y-axis direction. In one example, the lower wire 511 extends from the first electrode pad 181 to the resistive element R1, which is connected to the first electrode 142.

The via 521 connects the lower wire 511 and the first electrode pad 181.

The vias 522 and 523 connect the lower wire 511 and the first electrode 141. The vias 522 and 523 are located at opposite sides of the center O1 of the slot 321. The vias 522 and 523 are connected to opposite ends of the first electrode 141 in the Y-axis direction.

The vias 524 and 525 connect the lower wire 511 and the first electrode 142. The vias 524 and 525 are located at opposite sides of the center O2 of the slot 322. The vias 524 and 525 are connected to opposite ends of the first electrode 142 in the Y-axis direction.

The lower wire 511 may be used to connect the resistive elements R1 and R2 to the first electrodes 141 and 142.

In the lower wire 511, the portion between the via 522 and the via 523 may be omitted. Further, in the lower wire 511, the portion between the via 524 and the via 525 may be omitted.

The second electrode pad 181b is arranged next to the first electrode pad 181 in the X-axis direction. The second electrode pad 181b may be arranged along the first side 151 of the second electrode 150. The second electrode pad 181b may be arranged along the first side 151 of the second electrode 150 at the same position as the first electrode pad 181 in the X-axis direction.

### Advantages

### The fifth embodiment has the advantages described below.

5-1 The terahertz device 500 in accordance with the fifth embodiment has the same advantages as the terahertz device 300 in accordance with the third embodiment.

5-2 The terahertz device 500 in accordance with the fifth embodiment allows a connection for supplying power to the first electrode 141 and the second electrode 150 to be omitted.

### Sixth Embodiment

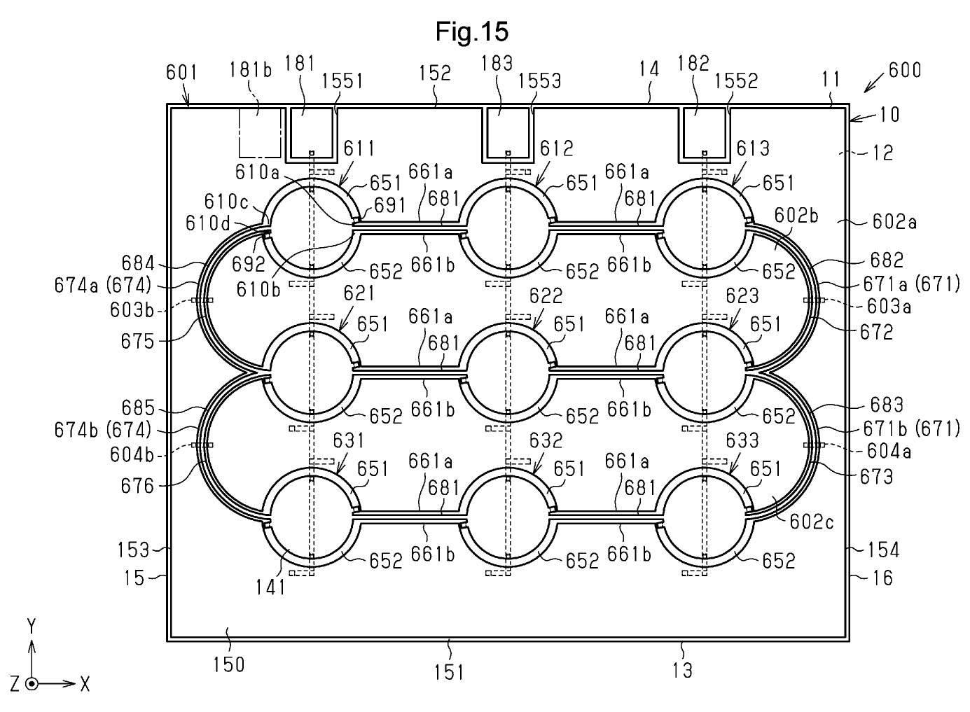

With reference to FIG. 15, a terahertz device 600 in accordance with a sixth embodiment will now be described.

In the sixth embodiment, same reference numerals are given to those components that are the same as the corresponding components of the first to fifth embodiments. Such components will not be described in detail.

The terahertz device 600 in accordance with the sixth embodiment differs from the terahertz devices 100, 200, 300, 400, and 500 in accordance with the above embodiments in that there is an array of slots. Thus, the description of the sixth embodiment will focus on such differences from the first to fifth embodiments.

### Schematic Configuration of Terahertz Device

FIG. 15 is a schematic plan view of an exemplary terahertz device 600 in accordance with the sixth embodiment.

The terahertz device 600 in accordance with the sixth embodiment may include nine the slots 611 to 613, 621 to 623, and 631 to 633 formed in a conductive layer 601. The slots 611 to 613, 621 to 623, and 631 to 633 are separated from one another in the X-axis direction and the Y-axis direction. The slots 611 to 613, 621 to 623, and 631 to 633 are arranged in the X-axis direction and the Y-axis direction in an array of three rows and three columns.

### Slots

The slots 611 to 613, 621 to 623, and 631 to 633 each include a first part 651 and a second part 652. The first part 651 and the second part 652 are semicircular. The first part 651 is separated from the second part 652 in the Y-axis direction. The first part 651, which is semicircular, is open toward the second part 652. The second part 652, which is semicircular, is open toward the first part 651. The first part 651 and the second part 652 open the annular slots 611 to 613, 621 to 623, and 631 to 633 at opposite sides in the X-axis direction.

The first part 651 includes a first end 610a and a third end 610c at the side opposite to the first end 610a. The second part 652 includes a second end 610b and a fourth end 610d at the side opposite to the second end 610b. The first end 610a of the first part 651 and the second end 610b of the second part 652 are separated from each other in the Y-axis direction. The third end 610c of the first part 651 and the fourth end 610d of the second part 652 are separated from each other in the Y-axis direction.

### Connecting Slits

Adjacent ones of the slots 611 to 613, 621 to 623, and 631 to 633 in the X-axis direction are connected by connecting slits 661a and 661b. Each connecting slit 661a connects the first parts 651 of two of the slots 611 to 613, 621 to 623, and 631 to 633 that are adjacent to each other in the X-axis direction. Each connecting slit 661b connects the second parts 652 of two of the slots 611 to 613, 621 to 623, and 631 to 633 that are adjacent to each other in the X-axis direction. As an example, the slots 611 and 612 that are adjacent to each other in the X-axis direction will now be described. The connecting slit 661a connects the first end 610a of the first part 651 in the slot 611 and the third end 610c of the first part 651 in the slot 612. The connecting slit 661b connects the second end 610b of the second part 652 in the slot 611 and the fourth end 610d of the second part 652 in the slot 612. The above description of the slots 611 and 612 also applies to the other slots, namely, the slots 612 and 613, the slots 621 and 622, the slots 622 and 623, the slots 631 and 632, and the slots 632 and 633.

Among the slots 611 to 613, 621 to 623, and 631 to 633, the slots arranged at one end in the X-axis direction are the slots 613, 623, and 633 that are separated from one another in the Y-axis direction. The slots 613, 623, and 633 are arranged along the side surface 16 of the substrate 10. Among the slots 613, 623, and 633 aligned in the Y-axis direction, the slots 613 and 633 arranged at opposite ends in the Y-axis direction will be referred to as the first end slot 613 and the second end slot 633. The slot 623 located between the first end slot 613 and the second end slot 633 in the Y-axis direction will be referred to as the intermediate slot 623. The terahertz device 600 in accordance with the sixth embodiment includes one intermediate slot 623 located between the first end slot 613 and the second end slot 633. The quantity of the intermediate slot 623 may be changed.

The first end slot 613, the second end slot 633, and the intermediate slot 623 are connected by connecting slits 671, 672, and 673.

The connecting slit 671 connects the first end 610a of the first part 651 in the first end slot 613 to the second end 610b of the second part 652 in the second end slot 633. The connecting slit 671 includes two semicircular connecting portions 671a and 671b connected in the Y-axis direction. The quantity of the connecting portions is varied in accordance with the quantity of slots aligned in the Y-axis direction.

The connecting slit 672 connects the second end 610b of the second part 652 in the first end slot 613 and the first end 610a of the first part 651 in the intermediate slot 623. The connecting slit 672 is referred to as “the first intermediate connecting slit.” The connecting slit 673 connects the second end 610b of the second part 652 in the intermediate slot 623 and the first end 610a of the first part 651 in the second end slot 633. The connecting slit 673 corresponds to “the second intermediate connecting slit.” The connecting slits 672 and 673 are arcuate.

Among the slots 611 to 613, 621 to 623, and 631 to 633, the slots 611, 621, and 631 that are arranged at the end opposite to the slots 613, 623, and 633 in the X-axis direction are separated from one another in the Y-axis direction. The slots 611, 621, and 631 are arranged along the side surface 15 of the substrate 10. Among the slots 611, 621, and 631 aligned in the Y-axis direction, the slots 611 and 631 arranged at opposite ends in the Y-axis direction will be referred to as the first end slot 611 and the second end slot 631. The slot 621 located between the first end slot 611 and the second end slot 631 in the Y-axis direction will be referred to as the intermediate slot 621. The terahertz device 600 in accordance with the sixth embodiment includes one intermediate slot 621 located between the first end slot 611 and the second end slot 631. The quantity of the intermediate slot 621 may be changed.

The first end slot 611, the second end slot 631, and the intermediate slot 621 are connected by connecting slits 674, 675, and 676.

The connecting slit 674 connects the third end 610c of the first part 651 in the first end slot 611 to the fourth end 610d of the second part 652 in the second end slot 631. The connecting slit 674 includes two arcuate connecting portions 674a and 674b connected in the Y-axis direction. The quantity of the connecting portions is varied in accordance with the quantity of slots aligned in the Y-axis direction.

The connecting slit 675 connects the fourth end 610d of the second part 652 in the first end slot 611 and the third end 610c of the first part 651 in the intermediate slot 621. The connecting slit 675 corresponds to “the third intermediate connecting slit.” The connecting slit 676 connects the fourth end 610d of the second part 652 in the intermediate slot 621 and the third end 610c of the first part 651 in the second end slot 631. The connecting slit 676 is referred to as “the fourth intermediate connecting slit.” The connecting slits 675 and 676 are arcuate.

### First Electrodes and Second Electrode

The conductive layer 601 includes the first electrodes 141 defined by the slots 611 to 613, 621 to 623, and 631 to 633. In one example, the first electrodes 141 are circular in plan view. The first electrodes 141 are separated from one another in the X-axis direction and the Y-axis direction.

The second parts 652 of the slots 611 to 613, the first parts 651 of the slots 621 to 623, the connecting slits 661b between the slots 611 to 613, the connecting slits 661a between the slots 621 to 623, the connecting slit 672, and the connecting slit 675 define a first electrode portion 602b.

The second parts 652 of the slots 621 to 623, the first parts 651 of the slots 631 to 633, the connecting slits 661b between the slots 621 to 623, the connecting slits 661a between the slots 631 to 633, the connecting slit 673, and the connecting slit 676 define a second electrode portion 602c.

The second electrode 150 includes a peripheral portion 602a surrounding the slots 611 to 613, 621 to 623, and 631 to 633. The first electrode portion 602b is electrically connected by first interconnections 603a and 603b to the peripheral portion 602a. The second electrode portion 602c is electrically connected by the second interconnections 604a and 604b to the peripheral portion 602a. The first electrode portion 602b, the second electrode portion 602c, and the peripheral portion 602a form the second electrode 150.

The first interconnections 603a and 603b may each include, for example, a lower wire, a via, and the like. The lower wire of the first interconnection 603a intersects the connecting portion 671a of the connecting slit 671, the connecting slit 672, and a connection line 682. The lower wire of the first interconnection 603b intersects the connecting portion 674a of the connecting slit 674, the connecting slit 675, and a connection line 684. The second interconnections 604a and 604b may each include, for example, a lower wire, a via, and the like. The lower wire of the second interconnection 604a intersects the connecting portion 671b of the connecting slit 671, the connecting slit 673, and a connection line 683. The lower wire of the second interconnection 604b intersects the connection portion 674b of the connecting slit 674, the connecting slit 676, and a connection line 685. The first interconnections 603a and 603b extend across the connecting slits 671 (671a), 672, 674 (674a), and 675 and the connection lines 682 and 684. The second interconnections 604a and 604b extend across the connecting slits 671 (671b), 673, 674 (674b), and 676 and the connection lines 683 and 685.

### Connection Lines

The conductive layer 601 includes connection lines 681 connecting the first electrodes 141 in the slots 611 to 613, 621 to 623, and 631 to 633 aligned in the X-axis direction. The conductive layer 601 includes the connection lines 682 and 683 connecting the slots 613, 623, and 633 aligned in the Y-axis direction, and the connection lines 684 and 685 connecting the slots 611, 621, and 631 aligned in the Y-axis direction.

### Active Elements

The terahertz device 600 includes a first active element 691 and a second active element 692 that are disposed in each of the slots 611 to 613, 621 to 623, and 631 to 633.

The first active element 691 is disposed at the first end 610a of the first part 651 in each of the slots 611 to 613, 621 to 623, and 631 to 633. The second active element 692 is disposed at the fourth end 610d of each second part 652. The first end 610a of the first part 651 and the fourth end 610d of the second part 652 are located at opposite sides of the center of each of the slots 611 to 613, 621 to 623, and 631 to 633. Thus, the first active element 691 and the second active element 692 are disposed in each of the slots 611 to 613, 621 to 623, and 631 to 633 along a straight reference line extending through the center of each of the slots 611 to 613, 621 to 623, and 631 to 633.

The first active element 691 and the second active element 692 may be, for example, RTDs. The first active element 691 and the second active element 692 may each be a diode, other than an RTD, or a transistor. Examples of other active elements include, for example, a TUNNETT diode, an IMPATT diode, a GaAs FET, a GaN FET, an HEMT, an HBT, and a CMOS FET.

The first active element 691 and the second active element 692 are connected in parallel to the first electrode 141 and the second electrode 150.

### First Electrode Pads and Second Electrode Pads

A first electrode pad 181 is aligned with the first electrodes 141 in the slots 611, 621, and 631. The first electrode pad 181 is electrically connected by an interconnection 51 to the first electrodes 141.

The first electrode pad 182 is aligned with the first electrodes 141 in the slots 612, 622, and 632. The first electrode pad 182 is electrically connected by an interconnection 52 to the first electrode 141.

The first electrode pad 183 is aligned with the first electrodes 141 in the slots 613, 623, and 633. The first electrode pad 183 is electrically connected by an interconnection 53 to the first electrode 141.

The second electrode pad 181b is arranged next to the first electrode pad 181 in the X-axis direction. The second electrode pad 181b may be arranged along the first side 151 of the second electrode 150. The second electrode pad 181b may be arranged along the first side 151 of the second electrode 150 at the same position as one of the first electrode pads 181, 182, and 183 in the X-axis direction.

### Advantages

### The sixth embodiment has the advantages described below.

6-1 The terahertz device 600 in accordance with the sixth embodiment has the same advantages as the embodiments described above.

6-2 The terahertz device 600 in accordance with the sixth embodiment includes the first electrodes 141, which are defined by the slots 611 to 613, 621 to 623, and 631 to 633 arranged in an array, and the first active element 691 and the second active element 692, which are disposed in each of the slots 611 to 613, 621 to 623, and 631 to 633. This allows the terahertz device 600 to emit electromagnetic waves with a high output.

### Seventh Embodiment

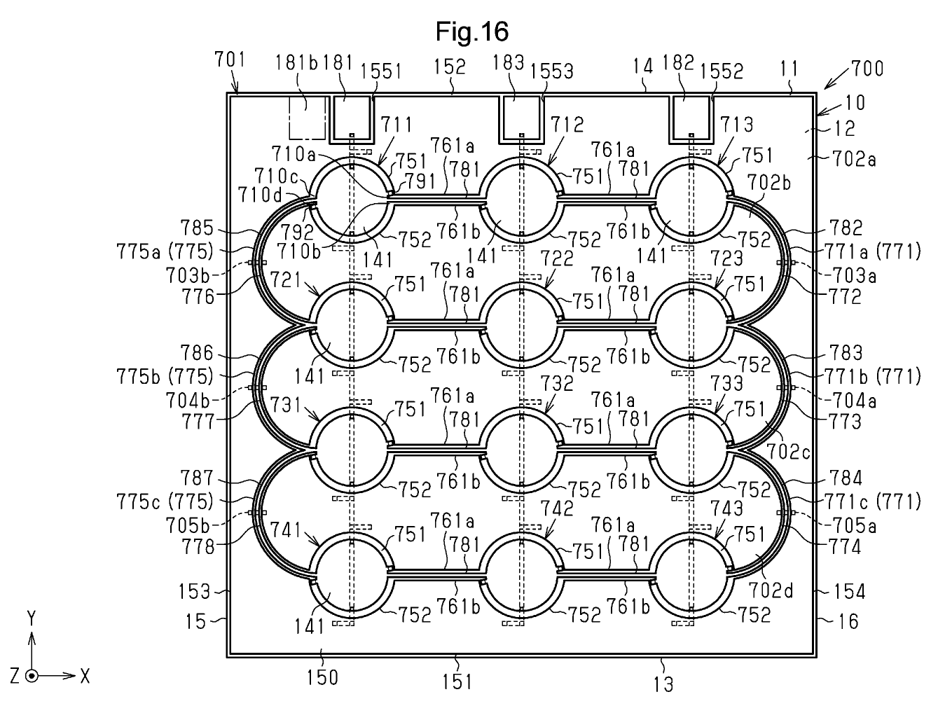

With reference to FIG. 16, the terahertz device 700 in accordance with the seventh embodiment will now be described.

In the seventh embodiment, same reference numerals are given to those components that are the same as the corresponding components of the sixth embodiment. Such components will not be described in detail.

The terahertz device 700 in accordance with the seventh embodiment differs from the terahertz device 600 in accordance with the sixth embodiment mainly in the connecting slits for the array of slots 711 to 713, 721 to 723, 731 to 733, and 741 to 743. Thus, the description of the seventh embodiment will focus on such differences from the sixth embodiment.

### Schematic Configuration of Terahertz Device

The terahertz device 700 in accordance with the seventh embodiment includes the slots 711 to 713, 721 to 723, 731 to 733, and 741 to 743. The slots 711 to 713, 721 to 723, 731 to 733, and 741 to 743 are arranged in the X-axis direction and the Y-axis direction in an array of four rows and three columns.

The slots 711 to 713, 721 to 723, 731 to 733, and 741 to 743 each include a first part 751 and a second part 752. The first part 751 and the second part 752 are similar to the first part 651 and the second part 652 of the sixth embodiment. In the same manner as the first part 651 and the second part 652 in the sixth embodiment, the first part 751 and the second part 752 includes a first end 710a, a second end 710b, a third end 710c, and a fourth end 710d.

In the same manner as the sixth embodiment, the first parts 751 and the second parts 752 of the slots 711 to 713 in the seventh embodiment are connected by connecting slits 761a and 761b. In the same manner as the sixth embodiment, the first parts 751 and the second parts 752 of the slots 721 to 723 are connected by the connecting slits 761a and 761b. The first part 751 of the slot 721 corresponds to “the fifth part,” and the second part 752 of the slot 721 corresponds to “the sixth part.” In the same manner as the sixth embodiment, the first parts 751 and the second parts 752 of the slots 731 to 733 are connected by the connecting slits 761a and 761b. The first part 751 of the slot 731 corresponds to “the fifth part,” and the second part 752 of the slot 731 corresponds to “the sixth part.” In the same manner as the sixth embodiment, the first parts 751 and the second parts 752 of the slots 741 to 743 are connected by the connecting slits 761a and 761b. The first part 751 of the slot 741 corresponds to “the third part,” and the second part 752 of the slot 741 corresponds to “the fourth part.”

The first electrodes 141 in the slots 711 to 713 are connected by connection lines 781. The first electrodes 141 in the slots 721 to 723 are connected by connection lines 781. The first electrodes 141 in the slots 731 to 733 are connected by connection lines 781. The first electrodes 141 in the slots 741 to 743 are connected by connection lines 781.

Among the slots 713, 723, 733, and 743 aligned in the Y-axis direction, the slots 713 and 743 arranged at opposite ends in the Y-axis direction will be referred to as the first end slot 713 and the second end slot 743. The slots 723 and 733 located between the first end slot 713 and the second end slot 743 in the Y-axis direction will be referred to as the intermediate slots 723 and 733. The terahertz device 700 in accordance with the seventh embodiment includes the two intermediate slots 723 and 733 located between the first end slot 713 and the second end slot 743.

The first end slot 713, the second end slot 743, and the intermediate slots 723 and 733 are connected by connecting slits 771, 772, 773, and 774.

The connecting slit 771 connects the first end 710a of the first part 751 in the first end slot 713 and the second end 710b of the second part 752 in the second end slot 743. In accordance with the quantity of slots aligned in the Y-axis direction, the connecting slit 771 includes three semicircular connecting portions 771a, 771b, and 771c connected in the Y-axis direction.

The connecting slit 772 connects the second end 710b of the second part 752 in the first end slot 713 and the first end 710a of the first part 751 in the intermediate slot 723. The connecting slit 772 corresponds to “the first intermediate connecting slit.” The connecting slit 773 connects the second end 710b of the second part 752 in the intermediate slot 723 and the first end 710a of the first part 751 in the intermediate slot 733. The connecting slit 773 corresponds to “the fifth intermediate connecting slit.” The connecting slit 774 connects the second end 710b of the second part 752 in the intermediate slot 733 and the first end 710a of the first part 751 in the second end slot 743. The connecting slit 774 corresponds to “the second intermediate connecting slit.” The connecting slits 772, 773, and 774 are arcuate.

Among the slots 711, 721, 731, and 741 aligned in the Y-axis direction, the slots 711 and 741 arranged at opposite ends in the Y-axis direction will be referred to as the first end slot 711 and the second end slot 741. The slots 721 and 731 located between the first end slot 711 and the second end slot 741 in the Y-axis direction will be referred to as the intermediate slots 721 and 731. The terahertz device 700 in accordance with the seventh embodiment includes the two intermediate slots 721 and 731 located between the first end slot 711 and the second end slot 741.

The first end slot 711, the second end slot 741, and the intermediate slots 721 and 731 are connected by connecting slits 775, 776, 777, and 778.

The connecting slit 775 connects the third end 710c of the first part 751 in the first end slot 711 and the fourth end 710d of the second part 752 in the second end slot 741. In accordance with the quantity of the slots aligned in the Y-axis direction, the connecting slit 775 includes three semicircular connecting portions 775a, 775b, and 775c connected in the Y-axis direction.

The connecting slit 776 connects the fourth end 710d of the second part 752 in the first end slot 711 and the third end 710c of the first part 751 in the intermediate slot 721. The connecting slit 776 corresponds to “the third intermediate connecting slit.” The connecting slit 777 connects the fourth end 710d of the second part 752 in the intermediate slot 721 and the third end 710c of the first part 751 in the intermediate slot 731. The connecting slit 777 corresponds to “the sixth intermediate slit.” The connecting slit 778 connects the fourth end 710d of the second part 752 in the intermediate slot 731 and the third end 710c of the first part 751 in the second end slot 741. The connecting slit 778 corresponds to “the second intermediate connecting slit.” The connecting slits 776, 777, and 778 are arcuate.

### First Electrodes and Second Electrode

The conductive layer 601 includes the first electrode 141 defined by the slots 711 to 713, 721 to 723, 731 to 733, and 741 to 743. In one example, the first electrodes 141 are circular in plan view. The first electrodes 141 are separated from one another in the X-axis direction and the Y-axis direction.

The second parts 752 of the slots 711 to 713, the first parts 751 of the slots 721 to 723, the connecting slits 761b between the slots 711 to 713, the connecting slits 761a between the slots 721 to 723, the connecting slit 772, and the connecting slit 776 define a first electrode portion 702b. The second parts 752 of the slots 721 to 723, the first parts 751 of the slots 731 to 733, the connecting slits 761b between the slots 721 to 723, the connecting slits 761a between the slots 731 to 733, the connecting slit 773, and the connecting slit 777 define a second electrode portion 702c. The second parts 752 of the slots 731 to 733, the first parts 751 of the slots 741 to 743, the connecting slits 761b between the slots 731 to 733, the connecting slits 761a between the slots 741 to 743, the connecting slit 774, and the connecting slit 778 define a third electrode portion 702d.

The second electrode 150 includes a peripheral portion 702a surrounding the slots 711 to 713, 721 to 723, 731 to 733, and 741 to 743. The first electrode portion 702b is electrically connected by first interconnections 703a and 703b to the peripheral portion 702a. The second electrode portion 702c is electrically connected by second interconnections 704a and 704b to the peripheral portion 702a. The third electrode portion 702d is electrically connected to the peripheral portion 702a by third interconnections 705a and 705b. The first electrode portion 702b, the second electrode portion 702c, the third electrode portion 702d, and the peripheral portion 702a form the second electrode 150.

The first interconnections 703a and 703b may each include, for example, a lower wire, a via, and the like. The lower wire of the first interconnection 703a intersects the connecting portion 771a of the connecting slit 771, the connecting slit 772, and a connection line 782. The lower wire of the first interconnection 703b intersects the connecting portion 775a of the connecting slit 775, the connecting slit 776, and a connection line 785. The second interconnections 704a and 704b may each include, for example, a lower wire, a via, and the like. The lower wire of the second interconnection 704a intersects the connection portion 771b of the connecting slit 771, the connecting slit 773, and a connection line 783. The lower wire of the second interconnection 704b intersects the connection portion 775b of the connecting slit 775, the connecting slit 777, and a connection line 786. The first interconnections 705a and 705b may each include, for example, a lower wire, a via, and the like. The lower wire of the third interconnection 705a intersects the connection portion 771c of the connecting slit 771, the connecting slit 774, and a connection line 784. The lower wire of the third interconnection 705b intersects the connection portion 775c of the connecting slit 775, the connecting slit 778, and a connection line 787. The first interconnections 703a and 703b may extend across the connecting slits 771 (771a), 772, 775 (775a), and 776 and the connection lines 782 and 785. The second interconnections 704a and 704b may extend across the connecting slits 771 (771b), 773, 775 (775b), and 777 and the connection lines 783 and 786. The third interconnections 705a and 705b may extend across the connecting slits 771 (771c), 774, 775 (775c), and 778 and the connection lines 784 and 787.

### Connection Lines

A conductive layer 701 includes the connection lines 781 connecting the first electrodes 141 in the slots 711 to 713, 721 to 723, 731 to 733, and 741 to 743 aligned in the X-axis direction. The conductive layer 701 includes the connection lines 782, 783, and 784 connecting the first electrodes 141 in the slots 713, 723, 733, and 743 aligned in the Y-axis direction. Further, the conductive layer 701 includes the connection lines 785, 786, and 787 connecting the first electrodes 141 in the slots 711, 721, 731, and 741.

### Active Elements

The terahertz device 700 includes a first active element 791 and a second active element 792 disposed in each of the slots 711 to 713, 721 to 723, 731 to 733, and 741 to 743.

The first active element 791 is disposed at the first end 710a of the first part 751 in each of the slots 711 to 713, 721 to 723, and 731 to 733. The second active element 792 is disposed at the fourth end 710d of each second part 752. The first end 710a of the first part 751 and the fourth end 710d of the second part 752 are located at opposite sides of the center of each of the slots 711 to 713, 721 to 723, and 731 to 733. Thus, the first active element 791 and the second active element 792 are disposed in each of the slots 711 to 713, 721 to 723, and 731 to 733 along a straight reference line extending through the center of each of the slots 711 to 713, 721 to 723, and 731 to 733.

The first active element 791 and the second active element 792 may be, for example, RTDs. The first active element 791 and the second active element 792 may each be a diode, other than an RTD, or a transistor. Examples of other active elements include, for example, a TUNNETT diode, an IMPATT diode, a GaAs FET, a GaN FET, an HEMT, an HBT, and a CMOS FET.

The first active element 791 and the second active element 792 are connected in parallel to the first electrode 141 and the second electrode 150.

### Advantages

### The seventh embodiment has the advantages described below.

(7-1) The terahertz device 700 in accordance with the seventh embodiment has the same advantages as the terahertz device 600 in accordance with the sixth embodiment. The terahertz device 700 in accordance with the seventh embodiment includes the first electrode 141, which are defined by the slots 711 to 713, 721 to 723, 731 to 733, and 741 to 743 that are arranged in an array, and the first active element 791 and the second active element 792, which are disposed in each of the slots 711 to 713, 721 to 723, 731 to 733, and 741 to 743. This allows the terahertz device 700 to emit electromagnetic waves with a high output.

### Eighth Embodiment

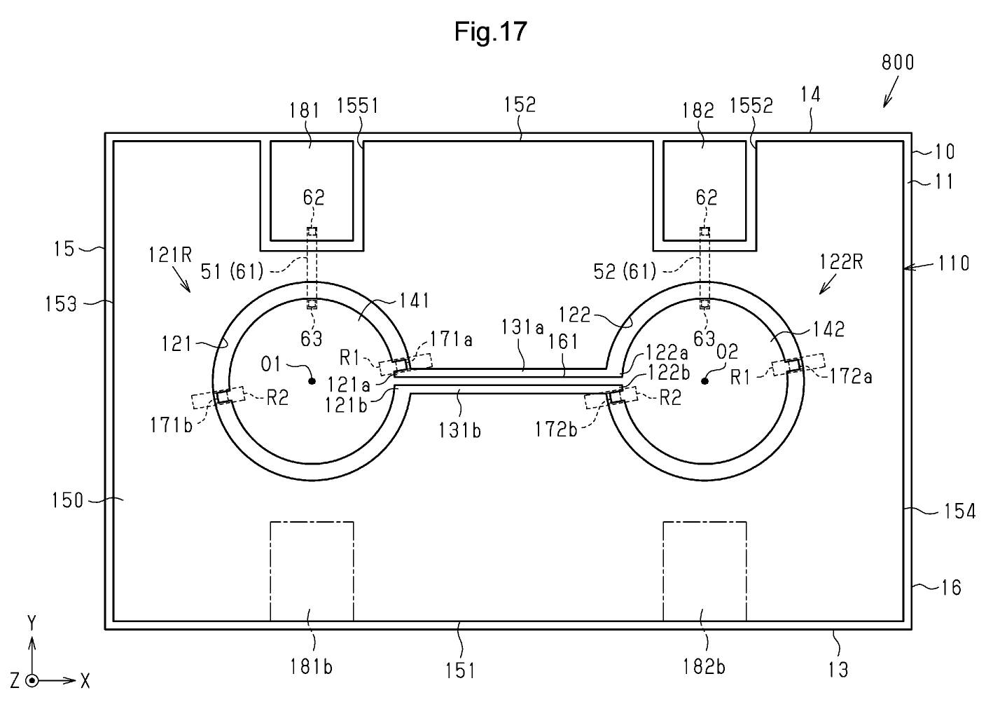

With reference to FIGS. 17 to 20, a terahertz device 800 in accordance with the eighth embodiment will now be described.

In the eighth embodiment, same reference numerals are given to those components that are the same as the corresponding components of the first embodiment. Such components will not be described in detail.

The terahertz device 800 in accordance with the eighth embodiment differs from the terahertz device 100 in accordance with the first embodiment mainly in the arrangement of the resistive elements R1 and R2. Thus, the description of the eighth embodiment will focus on such differences from the first embodiment.

### Schematic Configuration of Terahertz Device

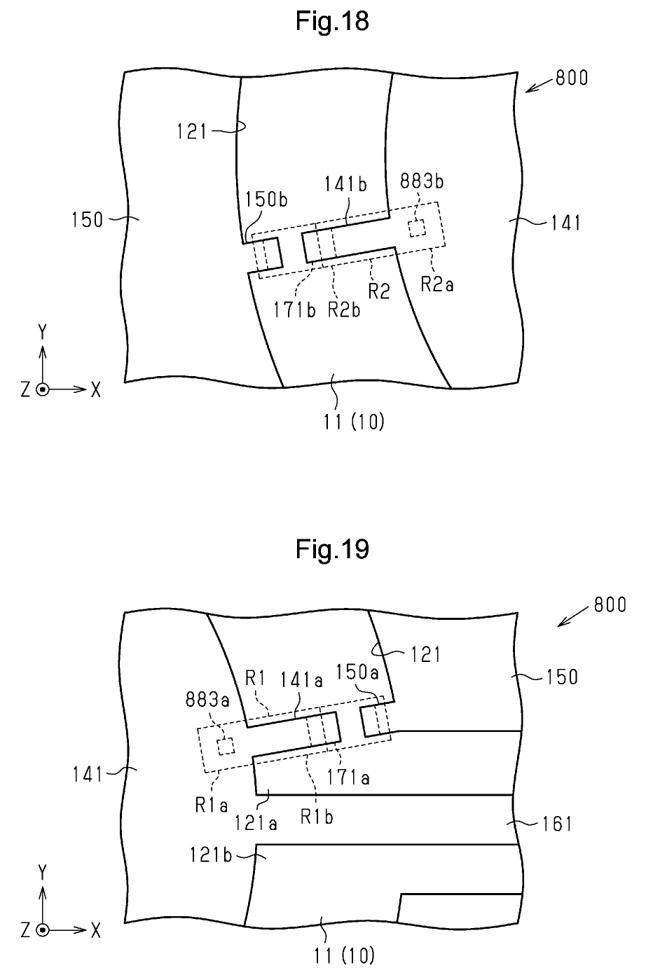

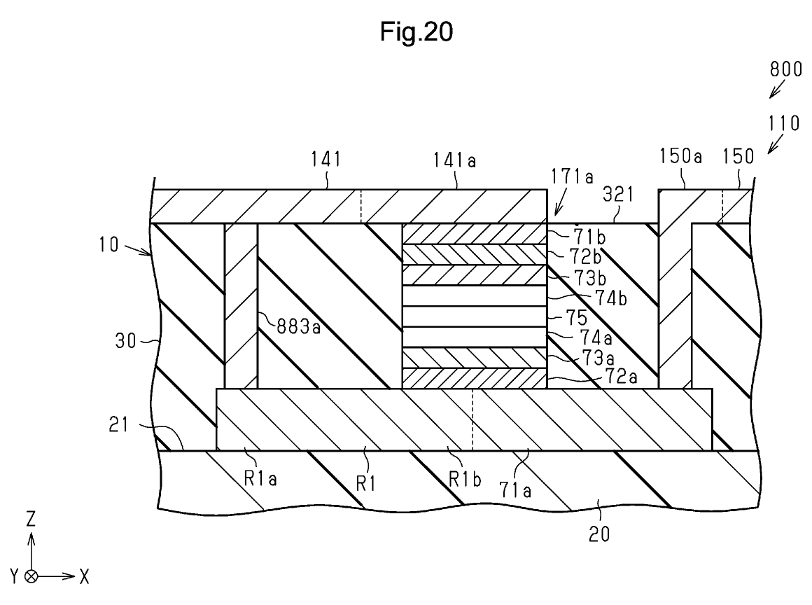

FIG. 17 is a schematic plan view of an exemplary terahertz device 800 in accordance with the eighth embodiment. FIG. 18 is a schematic plan view of part of the terahertz device 800 illustrated in FIG. 17 and shows the active element 171b and the resistive element R2. FIG. 19 is a schematic plan view of part of the terahertz device 800 illustrated in FIG. 17 and shows the active element 171a and the resistive element R1. FIG. 20 is a schematic cross-sectional view of the active element 171a and the resistive element R1 illustrated in FIG. 19.

As shown in FIG. 17, the terahertz device 800 in accordance with the eighth embodiment includes the resistive element R1, which overlaps the active elements 171a and 172a in plan view, and the resistive element R2, which overlaps the active elements 171b and 172b in plan view. The resistive element R1 is connected in parallel to the active elements 171a and 172a. The resistive element R2 is connected in parallel to the active elements 171b and 172b.

As shown in FIG. 18, the resistive element R2 overlaps the active element 171b in plan view. The resistive element R2 includes a first end R2a and a second end R2b. The second end R2b of the resistive element R2 is electrically connected to the active element 171b. The first end R2a of the resistive element R2 overlaps the first electrode 141. The first end R2a of the resistive element R2 is electrically connected to the first electrode 141 by a via 883b.

As shown in FIG. 19, the resistive element R1 overlaps the active element 171a in plan view. The resistive element R1 includes a first end R1a and a second end R1b. The second end R1b of the resistive element R1 is electrically connected to the active element 171a. The first end R1a of the resistive element R1 overlaps the first electrode 141. The first end R1a of the resistive element R1 is electrically connected to the first electrode 141 by a via 883a.

As shown in FIG. 20, the resistive element R1 is formed on the substrate front surface 21 of the semiconductor substrate 20. The resistive element R1 is disposed adjacent to the semiconductor layer 71a of the active element 171a. The GaInAs layer 72a of the active element 171a overlaps both the semiconductor layer 71a and the resistive element R1.

The semiconductor layer 71a and the resistive element R1 may be formed from the same material. In one example, the semiconductor layer 71a and the resistive element R1 are formed from GaInAs. The semiconductor layer 71a and the resistive element R1 may be doped with an n-type impurity at a high concentration. The resistive element R1 may be formed integrally with the semiconductor layer 71a. In FIG. 20, the broken line indicates the boundary between the semiconductor layer 71a and the resistive element R1. The broken line does not indicate a boundary that can actually be recognized. Although not shown in the drawings, the resistive element R2 is identical in structure to the resistive element R1.

The terahertz device 800 in accordance with the eighth embodiment has the functionality of a detector that detects terahertz waves.

As shown in FIGS. 17 to 19, the resistive element R2 is electrically connected in parallel to the active elements 171b and 172b. The resistive element R1 is electrically connected in parallel to the active elements 171a and 172a. The resistive element R2 and the resistive element R1 of the eighth suppress oscillation of the active elements 171b and 172b and the active elements 171a and 172a.

In addition to the advantages of the first embodiment, the eighth embodiment has the advantages described below.

(8-1) In the same manner as the terahertz device 100 in accordance with the first embodiment, the terahertz device 800 in accordance with the eighth embodiment includes the active elements 171a and 172a and the active elements 171b and 172b at opposite sides of the first electrodes 141 and 142. Further, the terahertz device 800 in accordance with the eighth embodiment detects terahertz waves with the active elements 171b and 172b and the active elements 171a and 172a. This allows the terahertz device 800 in accordance with the eighth embodiment to have a high resolution.

(8-2) The terahertz device 800 in accordance with the eighth embodiment includes the resistive element R2, which overlaps the active elements 171b and 172b, and the resistive element R1, which overlaps the active elements 171a and 172a. The resistive element R2 and the resistive element R1 suppress oscillation of the active elements 171b and 172b and the active elements 171a and 172a. Thus, the terahertz device 800 in accordance with the eighth embodiment suppresses oscillation of the active elements 171b and 172b and the active elements 171a and 172a.

### Modified Examples

The above embodiments may be modified as described below. The modified examples described below may be combined as long as there is no technical contradiction. In the modified examples described hereafter, same reference characters are given to those components that are the same as the corresponding components of the above embodiments. Such components will not be described in detail.

The reflective layer 40 may be omitted.

The semiconductor substrate 20 may be formed by a stack of substrates.

In this specification, the word “on” includes the meaning of “above” in addition to the meaning of “on” unless otherwise described in the context. Accordingly, the phrase of “first layer formed on second layer” may mean that the first layer is formed directly contacting the second layer in one embodiment and that the first layer is located above the second layer without contacting the second layer in another embodiment. Thus, the word “on” will also allow for a structure in which another layer is arranged between the first layer and the second layer.

The Z-axis direction as referred to in this specification does not necessarily have to be the vertical direction and does not necessarily have to fully coincide with the vertical direction. Accordingly, in the structures disclosed above (e.g., structure shown in FIG. 1), upward and downward in the Z-axis direction as referred to in this specification is not limited to upward and downward in the vertical direction. For example, the X-axis direction may be the vertical direction. Alternatively, the Y-axis direction may be the vertical direction.

### Clauses

Technical concepts that can be understood from each of the above embodiments and modified examples will now be described. Reference characters used in the described embodiment are added to corresponding elements in the clauses to aid understanding without any intention to impose limitations to these elements. The reference characters are given as examples to aid understanding and not intended to limit elements to the elements denoted by the reference characters.

Clause 1 A terahertz device, comprising: a substrate (10) including a front surface (11) and a back surface (12); a conductive layer (110) formed on the front surface (11); slots (121, 122) formed in the conductive layer (110); connecting slits (131a, 131b) formed in the conductive layer (110); and active elements (171a, 171b, 172a, 172b) disposed in the slots and configured to oscillate or detect electromagnetic waves, where each of the slots has an annular shape, the conductive layer (110) includes first electrodes (141, 142) respectively defined by the slots, a connection line (161) disposed in the connecting slits and electrically connecting the first electrodes located inside two adjacent ones of the slots, and a second electrode (150) located outside the slots, each of the connecting slits (131a, 131b) connects the two adjacent ones of the slots and insulates the connection line from the second electrode, the active elements include two active elements provided for each of the first electrodes, and the two active elements are located at opposite sides of the corresponding one of the first electrodes with respect to a center of the corresponding one of the slots in a plan view taken from a direction orthogonal to the front surface (11).

Clause 2 The terahertz device according to clause 1, where: the slots include a first slot (121) having the annular shape that is open and including a first end (121a) and a second end (121b), and a second slot (122) having the annular shape that is open and including a first end (122a) and a second end (122b); the connecting slits include a first connecting slit (131a) connecting the first end (121a) of the first slot (121) and the first end (122a) of the second slot (122), and a second connecting slit (131b) connecting the second end (121b) of the first slot (121) and the second end (122b) of the second slot (122); and the active elements include a first active element (171a) disposed in the first slot (121) at the first end (121a), a second active element (171b) disposed in the first slot (121) at an opposite side of the first end with respect to the center (O1) of the first slot, a third active element (172b) disposed in the second slot (122) at the second end (122b), and a fourth active element (172a) disposed in the second slot (122) at an opposite side of the second end with respect to the center (O2) of the second slot.

Clause 3The terahertz device according to clause 2, where: the first slot (121) is separated from the second slot (122) in a first direction (X); the first slot (121) has the open annular shape in which the first end and the second end are separated in a second direction (Y) that is orthogonal to the first direction; the second slot (122) has the open annular shape in which the first end and the second end are separated in the second direction; the first slot and the second slot are arranged so that the first ends (121a, 122a) of the first slot and the second slot are both located in a same direction in the second direction relative to the second ends (121b, 122b) of the first slot and the second slot; the first connecting slit (131a) extends in the first direction and connects the first ends (121a, 122a) to each other; the second connecting slit (131b) extends in the first direction and connects the second ends (121b, 122b) to each other; and the first connecting slit and the second connecting slit are parallel and separated in the second direction, and the connection line (161) extends in the first direction.

Clause 4 The terahertz device according to clause 2, where: the first slot (121) is separated from the second slot (123) in a first direction (X); the first slot (121) has the open annular shape in which the first end (121a) is separated from the second end (121b) in a second direction (Y) that is orthogonal to the first direction; the second slot (123) includes a first part (221) and a second part (222) that are semicircular and separated from each other in the second direction, and the first part and the second part form the annular shape that is open at opposite sides in the first direction; the first part (221) includes the first end (123a) separated from the first end (121a) of the first slot (121) in the first direction, and a third end (123c) located at an opposite side of the first end (123a) of the second slot (123); the second part (222) includes the second end (123b) separated from the second end (121b) of the first slot in the first direction, and a fourth end (123d) located at an opposite side of the second end (123b) of the second slot (123) and separated from the third end in the second direction; and the fourth active element (173a) is disposed at the third end (123c).

Clause 5 The terahertz device according to clause 2, where: the first slot (321) is separated from the second slot (322) in a second direction (Y); the first slot has the annular shape in which the first and second ends (321a, 321b) of the first slot are separated in the second direction; the second slot has the annular shape in which the first and second ends (322a, 322b) of the second slot are separated in the second direction; the first end (321a) of the first slot (321) is located opposite to the second slot (322) with respect to the second end (321b) of the first slot; and the first end (322a) of the second slot (322) is located opposite to the first slot (321) with respect to the second end (322b) of the second slot.

Clause 6 The terahertz device according to clause 5, where: the first slot (321) includes a first part (331a) and a second part (331b) that are semicircular and separated from each other in the second direction, and the first part and the second part form the annular shape that is open at two opposite sides; the second slot (322) includes a third part (332a) and a fourth part (332b) that are semicircular and separated from each other in the second direction, and the third part and the fourth part form the annular shape that is open at two opposite sides; the first part includes the first end (321a) of the first slot, and a third end (321c) located at an opposite side of the first end; the second part includes the second end (321b) of the first slot, and a fourth end (321d) located at an opposite side of the second end; the third part includes the first end (322a) of the second slot, and a third end (322c) located at an opposite side of the first end; the fourth part includes the second end (322b) of the second slot, and a fourth end (322d) located at an opposite side of the second end; the first connecting slit (341a) connects the first end (321a) of the first part (331a) and the first end (322a) of the third part (332a); the second connecting slit (341b) connects the second end (321b) of the second part (331a) and the second end (322b) of the fourth part (332b); and the connecting slits include a third connecting slit (342a) connecting the third end (321c) of the first part (331a) and the third end (322c) of the third part (332a), and a fourth connecting slit (342b) connecting the fourth end (321d) of the second part (331b) and the fourth end (322d) of the fourth part (332b).

Clause 7 The terahertz device according to clause 1, where the slots include a first end slot (613, 713) and a second end slot (633, 743) aligned in a second direction and located at opposite ends in the second direction, and at least one intermediate slot (623, 723, 733) located between the first end slot and the second end slot; the first end slot (613, 713) has the annular shape that is open and includes a first end (610a, 710a) and a second end (610b, 710b) that are separated in the second direction; the second end slot (633, 743) has the annular shape that is open in a same direction as the first end slot and includes a first end (610a, 710a) and a second end (610b, 710b) that are separated in the second direction; the intermediate slot (623, 723, 743) has an annular shape that is open in the same direction as the first end slot and includes a first end (610a, 710a) and a second end (610b, 710b) that are separated in the second direction; the first end of the first end slot is located opposite to the intermediate slot with respect to the second end of the first end slot; the second end of the second end slot is located opposite to the intermediate slot with respect to the first end of the second end slot; the first end of the intermediate slot is located on a same side as the first end slot with respect to the second end of the intermediate slot; the connecting slits include a first connecting slit (671, 771) connecting the first end (610a, 710a) of the first end slot (613, 713) and the second end (610b, 710b) of the second end slot (633, 743), a first intermediate connecting slit (672, 772) connecting the second end (610b, 710b) of the first end slot (613, 713) and the first end (610a, 710a) of the intermediate slot (623, 723), and a second intermediate connecting slit (673, 774) connecting the second end (610b, 710b) of the intermediate slot (623, 733) and the first end (610a, 710a) of the second end slot; and the active elements include a first active element (791) disposed at the first end (610a, 710a) in each of the first end slot, the second end slot, and the intermediate slot, and a second active element (792) disposed at an opposite side of the first end with respect to the center in each of the first end slot, the second end slot, and the intermediate slot.

Clause 8 The terahertz device according to clause 7, where: the at least one intermediate slot (623, 723, 733) includes multiple intermediate slots; the multiple intermediate slots are arranged in the second direction; and the multiple connecting slits include a fifth intermediate connecting slit (773) connecting the second end (710b) of one (723) of two of the intermediate slots (723, 733) that are adjacent to each other in the second direction to the first end (710a) of the other one of the two of the intermediate slots that are adjacent to each other.

Clause 9 The terahertz device according to clause 7 or 8, where: the first end slot (611, 711) includes a first part (651, 751) and a second part (652, 752) that are semicircular and separated from each other in the second direction, and the first part and the second part form the annular shape that is open at opposite sides in the first direction; the second end slot (631, 741) includes a third part and a fourth part that are semicircular and separated from each other in the second direction, and the third part and the fourth part form the annular shape that is open at opposite sides in the first direction; the intermediate slot (621, 721, 731) includes a fifth part and a sixth part that are semicircular and separated from each other in the second direction, and the fifth part and the sixth part form the annular shape that is open at opposite sides in the first direction; the first part includes the first end (610a, 710a) of the first end slot, and a third end (610c, 710c) located at an opposite side of the first end; the second part includes the second end (610b, 710b) of the first end slot, and a fourth end (610d, 710d) located at an opposite side of the second end; the third part includes the first end of the second end slot and a third end located at an opposite side of the first end; the fourth part includes the second end of the second end slot, and a fourth end located at an opposite side of the second end; the fifth part includes the first end of the intermediate slot and a third end located at an opposite side of the first end; the sixth part includes the second end of the intermediate slot, and a fourth end located at an opposite side of the second end; and the connecting slits include a second connecting slit (674, 775) connecting the third end (610c, 710c) of the first part of the first end slot (613, 713) and the fourth end (610d, 710d) of the second part of the second end slot (631, 741), a third intermediate connecting slit (675, 776) connecting the fourth end (710d) of the second part of the first end slot (611, 711) and the third end (610c, 710c) of the fifth part of the intermediate slot (621, 721), and a fourth intermediate connecting slit (676, 778) connecting the fourth end (610c, 710d) of the sixth part of the intermediate slot (621, 731) and the third end (610c, 710c) of the first part of the second end slot (631, 741).

Clause 10 The terahertz device according to clause 9, where: the at least one intermediate slot (623, 723, 733) includes multiple intermediate slots; and the connecting slits include a sixth intermediate connecting slit (777) connecting two of the multiple intermediate slots (721, 731) that are adjacent to each other in the second direction at the fourth end (710d) of the sixth part and the third end (710c) of the fifth part.

Clause 11 The terahertz device according to any one of clauses 1 to 10, where: the two active elements (171a, 171b, 172a, 172b) are disposed at opposite sides of the first electrode (141, 142) along a straight reference line (LM1, LM2) extending through the center (O1, O2) of a corresponding one of the slots (121, 122) as viewed in the direction orthogonal to the front surface; and the straight reference line (LM1, LM2) is inclined relative to the connection line (161) as viewed in the direction orthogonal to the front surface.

Clause 12 The terahertz device according to any one of clauses 1 to 11, where the connection line (161) has a length that is one-half of an effective wavelength λg.

Clause 13 The terahertz device according to any one of clauses 1 to 12, where the connection line (161) has a length that is equal to an effective wavelength λg.

Clause 14 The terahertz device according to any one of clauses 1 to 13, further including resistive elements (R1, R2) electrically connected in parallel to the active elements (171a, 171b, 172a, 172b).

Clause 15 The terahertz device according to clause 14, where the resistive elements (R1, R2) are connected to imaginary short-circuit points of the first electrodes (141, 142).

Clause 16 The terahertz device according to clause 14, where the resistive elements (R1, R2) respectively overlap the active elements (171a, 171b, 172a, 172b) in the plan view.

Clause 17 The terahertz device according to any one of clauses 1 to 16, further including first electrode pads (181, 182) respectively connected to the first electrodes (141, 142).

Clause 18 The terahertz device according to clause 7 or 8, further including a first electrode pad (181) connected to the first electrodes (141, 142) that are aligned in the second direction.

Clause 19 The terahertz device according to clause 17, further including second electrode pads (181b, 182b) formed in the second electrode for each of the first electrodes.

Clause 20 The terahertz device according to any one of clauses 1 to 18, further including a second electrode pad (181b) formed in the second electrode.

Clause 21 The terahertz device according to any one of clauses 1 to 18, further including: a reflective layer (40) arranged on the back surface of the substrate (10) and configured to reflect the electromagnetic waves, where the reflective layer overlaps the slots in the plan view.

Clause 22 The terahertz device according to any one of clauses 1 to 21, where the active elements includes any one of a resonant tunneling diode, a tunnel injection transit time (TUNNETT) diode, an impact ionization avalanche transit time (IMPATT) diode, a GaAs field effect transistor (FET), a GaN FET, a high electron mobility transistor, a heterojunction bipolar transistor, and a complementary metal–oxide–semiconductor (CMOS) FET. Exemplary descriptions are given above. In addition to the elements and methods (manufacturing processes) described to illustrate the technology of this disclosure, a person skilled in the art would recognize the potential for a wide variety of combinations and substitutions. All replacements, modifications, and variations within the scope of the claims are intended to be encompassed in the present disclosure.

What is claimed is:

1. A terahertz device, comprising:
a substrate including a front surface and a back surface;
a conductive layer formed on the front surface;
slots formed in the conductive layer;
connecting slits formed in the conductive layer; and
active elements disposed in the slots and configured to oscillate or detect electromagnetic waves, wherein
each of the slots has an annular shape,
the conductive layer includes
first electrodes respectively defined by the slots,
a connection line disposed in the connecting slits and electrically connecting the first electrodes located inside two adjacent ones of the slots, and
a second electrode located outside the slots,
each of the connecting slits connects the two adjacent ones of the slots and insulates the connection line from the second electrode,
the active elements include two active elements provided for each of the first electrodes, and
the two active elements are located at opposite sides of the corresponding one of the first electrodes with respect to a center of the corresponding one of the slots in a plan view taken from a direction orthogonal to the front surface.

2. The terahertz device according to claim 1, wherein:
the slots include
a first slot having the annular shape that is open and including a first end and a second end, and
a second slot having the annular shape that is open and including a first end and a second end;
the connecting slits include
a first connecting slit connecting the first end of the first slot and the first end of the second slot, and
a second connecting slit connecting the second end of the first slot and the second end of the second slot; and
the active elements include
a first active element disposed in the first slot at the first end,
a second active element disposed in the first slot at an opposite side of the first end with respect to the center of the first slot,
a third active element disposed in the second slot at the second end, and
a fourth active element disposed in the second slot at an opposite side of the second end with respect to the center of the second slot.

3. The terahertz device according to claim 2, wherein:
the first slot is separated from the second slot in a first direction;
the first slot has the open annular shape wherein the first end and the second end are separated in a second direction that is orthogonal to the first direction;
the second slot has the open annular shape wherein the first end and the second end are separated in the second direction;
the first slot and the second slot are arranged so that the first ends of the first slot and the second slot are both located in a same direction in the second direction relative to the second ends of the first slot and the second slot;
the first connecting slit extends in the first direction and connects the first ends to each other;
the second connecting slit extends in the first direction and connects the second ends to each other; and
the first connecting slit and the second connecting slit are parallel and separated in the second direction, and the connection line extends in the first direction.

4. The terahertz device according to claim 2, wherein:
the first slot is separated from the second slot in a first direction;
the first slot has the open annular shape wherein the first end and the second end are separated in a second direction that is orthogonal to the first direction;
the second slot includes a first part and a second part that are semicircular and separated from each other in the second direction, and the first part and the second part form the annular shape that is open at opposite sides in the first direction;
the first part includes
the first end separated from the first end of the first slot in the first direction, and
a third end located at an opposite side of the first end of the second slot;
the second part includes
the second end separated from the second end of the first slot in the first direction, and
a fourth end located at an opposite side of the second end of the second slot and separated from the third end in the second direction; and
the fourth active element is disposed at the third end.

5. The terahertz device according to claim 2, wherein:
the first slot is separated from the second slot in a second direction;
the first slot has the annular shape wherein the first and second ends of the first slot are separated in the second direction;
the second slot has the annular shape wherein the first and second ends of the second slot are separated in the second direction;
the first end of the first slot is located opposite to the second slot with respect to the second end of the first slot; and
the first end of the second slot is located opposite to the first slot with respect to the second end of the second slot.

6. The terahertz device according to claim 5, wherein:
the first slot includes a first part and a second part that are semicircular and separated from each other in the second direction, and the first part and the second part form the annular shape that is open at two opposite sides;
the second slot includes a third part and a fourth part that are semicircular and separated from each other in the second direction, and the third part and the fourth part form the annular shape that is open at two opposite sides;
the first part includes the first end of the first slot, and a third end located at an opposite side of the first end;
the second part includes the second end of the first slot, and a fourth end located at an opposite side of the second end;
the third part includes the first end of the second slot, and a third end located at an opposite side of the first end;
the fourth part includes the second end of the second slot, and a fourth end located at an opposite side of the second end;
the first connecting slit connects the first end of the first part and the first end of the third part;
the second connecting slit connects the second end of the second part and the second end of the fourth part; and
the connecting slits include
a third connecting slit connecting the third end of the first part and the third end of the third part, and
a fourth connecting slit connecting the fourth end of the second part and the fourth end of the fourth part.

7. The terahertz device according to claim 1, wherein:
the slots include
a first end slot and a second end slot aligned in a second direction and located at opposite ends in the second direction, and
at least one intermediate slot located between the first end slot and the second end slot;
the first end slot has the annular shape that is open and includes a first end and a second end that are separated in the second direction;
the second end slot has the annular shape that is open in a same direction as the first end slot and includes a first end and a second end that are separated in the second direction;
the intermediate slot has an annular shape that is open in the same direction as the first end slot and includes a first end and a second end that are separated in the second direction;
the first end of the first end slot is located opposite to the intermediate slot with respect to the second end of the first end slot;
the second end of the second end slot is located opposite to the intermediate slot with respect to the first end of the second end slot;
the first end of the intermediate slot is located on a same side as the first end slot with respect to the second end of the intermediate slot;
the connecting slits include
a first connecting slit connecting the first end of the first end slot and the second end of the second end slot,
a first intermediate connecting slit connecting the second end of the first end slot and the first end of the intermediate slot, and
a second intermediate connecting slit connecting the second end of the intermediate slot and the first end of the second end slot; and
the active elements include
a first active element disposed at the first end in each of the first end slot, the second end slot, and the intermediate slot, and
a second active element disposed at an opposite side of the first end with respect to the center in each of the first end slot, the second end slot, and the intermediate slot.

8. The terahertz device according to claim 7, wherein:
the at least one intermediate slot includes multiple intermediate slots;
the intermediate slots are arranged in the second direction; and
the connecting slits include a fifth intermediate connecting slit connecting the second end of one of two of the intermediate slots that are adjacent to each other in the second direction to the first end of the other one of the two of the intermediate slots that are adjacent to each other.

9. The terahertz device according to claim 7, wherein:
the first end slot includes a first part and a second part that are semicircular and separated from each other in the second direction, and the first part and the second part form the annular shape that is open at opposite sides in the first direction;
the second end slot includes a third part and a fourth part that are semicircular and separated from each other in the second direction, and the third part and the fourth part form the annular shape that is open at opposite sides in the first direction;
the intermediate slot includes a fifth part and a sixth part that are semicircular and separated from each other in the second direction, and the fifth part and the sixth part form the annular shape that is open at opposite sides in the first direction;
the first part includes the first end of the first end slot, and a third end located at an opposite side of the first end;
the second part includes the second end of the first end slot, and a fourth end located at an opposite side of the second end;
the third part includes the first end of the second end slot and a third end located at an opposite side of the first end;
the fourth part includes the second end of the second end slot, and a fourth end located at an opposite side of the second end;
the fifth part includes the first end of the intermediate slot and a third end located at an opposite side of the first end;
the sixth part includes the second end of the intermediate slot, and a fourth end located at an opposite side of the second end; and
the connecting slits include
a second connecting slit connecting the third end of the first part of the first end slot and the fourth end of the second part of the second end slot,
a third intermediate connecting slit connecting the fourth end of the second part of the first end slot and the third end of the fifth part of the intermediate slot, and
a fourth intermediate connecting slit connecting the fourth end of the sixth part of the intermediate slot and the third end of the first part of the second end slot.

10. The terahertz device according to claim 9, wherein:
the at least one intermediate slot includes multiple intermediate slots;
the connecting slits include a sixth intermediate connecting slit connecting two of the intermediate slots that are adjacent to each other in the second direction at the fourth end of the sixth part and the third end of the fifth part.

11. The terahertz device according to claim 1, wherein:
the two active elements are disposed at opposite sides of the first electrode along a straight reference line extending through the center of a corresponding one of the slots as viewed in the direction orthogonal to the front surface; and
the straight reference line is inclined relative to the connection line as viewed in the direction orthogonal to the front surface.

12. The terahertz device according to claim 1, wherein the connection line has a length that is one-half of an effective wavelength λg.

13. The terahertz device according to claim 1, wherein the connection line has a length that is equal to an effective wavelength λg.

14. The terahertz device according to claim 1, further comprising resistive elements electrically connected in parallel to the active elements.

15. The terahertz device according to claim 14, wherein the resistive elements are connected to imaginary short-circuit points of the first electrodes.

16. The terahertz device according to claim 14, wherein the resistive elements respectively overlap the active elements in the plan view.

17. The terahertz device according to claim 1, wherein the active elements includes any one of a resonant tunneling diode, a tunnel injection transit time (TUNNETT) diode, an impact ionization avalanche transit time (IMPATT) diode, a GaAs field effect transistor (FET), a GaN FET, a high electron mobility transistor, a heterojunction bipolar transistor, and a complementary metal–oxide–semiconductor (CMOS) FET.
